(19) United States
(12) Patent Application Publication
(10) Pub. No.: US 2026/0040750 A1
(43) Pub. Date: Feb. 5, 2026

(54) EFFICIENT ASSEMBLY FOR LED DISPLAYS

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US)

(21) Appl. No.: 18/990,888

(22) Filed: Dec. 20, 2024

Related U.S. Application Data
(60) Provisional application No. 63/677,595, filed on Jul. 31, 2024.

(51) Int. Cl. H10H 29/80; H01L 25/075; H01L 25/16; H10H 29/01; H10H 29/02; H10H 29/49; H10H 29/855

(52) U.S. Cl. CPC H10H 29/962; H01L 25/0753; H01L 25/0756; H01L 25/167; H10H 29/012; H10H 29/02; H10H 29/49; H10H 29/855

(57) ABSTRACT

A display device comprises a plurality of singulated dies attached to a backplane. Each singulated die comprises a plurality of LEDs. A method of forming the display device comprises attaching the plurality of singulated dies to the backplane.

### CROSS REFERENCE TO RELATED APPLICATION

This application claims the benefit of U.S. Provisional Patent Application No. 63/677,595, filed Jul. 31, 2024, which is hereby incorporated by reference herein in its entirety.

### FIELD

The present disclosure relates to display devices and methods of manufacturing the same.

### BACKGROUND

Micro light emitting diode (microLED, micro-LED, μLED, or μ-LED) displays may provide benefits of higher resolution and increased brightness when compared to conventional display technologies. A typical microLED display may be a heterogeneous system that integrates microLEDs and control devices manufactured using different substrates and different process flows. Unfortunately, current manufacturing processes used to assemble separately manufactured microLEDs and control devices into a single display e.g., robot-aided pick-and-place processes, may be prohibitively expensive and time-consuming for most commercial applications. Accordingly, there exists a need in the art for improved microLED displays and methods of manufacturing the same.

### SUMMARY

Embodiments herein provide for display devices formed from singulated chips comprising a plurality of LEDs and methods for manufacturing the same. Advantageously, forming a display from singulated chips comprising a plurality of LEDs may be used to enable efficient fabrication of display devices.

One general aspect includes a display device comprising a plurality of singulated dies attached to a substrate (e.g., backplane, thin film transistor (TFT) backplane, amorphous silicon (a-Si) TFT backplane(s) (i.e., a-Si TFT) or silicon backplane or any suitable backplane), each singulated die comprising a plurality of LEDs.

In some embodiments, the singulated dies are singulated first dies, and the LEDs are first LEDs. The display device further comprises a plurality of singulated second dies overlaying the plurality of singulated first dies. Each singulated second die comprises a plurality of second LEDs.

In some embodiments, each die has an LED driver. In some embodiments, each die has a sensor. In some embodiments, each die may be directly hybrid bonded to a vertically adjacent die without use of an intervening adhesive.

In some embodiments, at least one replacement die is disposed to overlap at least one die. At least one replacement first die may be disposed to overlap at least one singulated first die. At least one replacement second die may be disposed to overlap at least one singulated second die. At least one replacement first die and at least one replacement second die may be disposed to overlap at least one singulated first die and at least one singulated second die.

In some embodiments, the first LEDs and second LEDs are edge emitting LEDs. Each singulated first die may further comprise a plurality of first waveguides. Each singulated second dies may further comprise a plurality of second waveguides. Light emitted from the first LEDs is guided by the first waveguides through the second waveguides towards a viewing surface of the display device. Light emitted by the second LEDs is guided by the second waveguides towards the viewing surface of the display device. In some embodiments, the second LEDs are surface emitting LEDs.

In some embodiments, the display device further comprises a plurality of singulated third dies disposed between the plurality of singulated first dies and the plurality of singulated second dies. Each singulated third die comprises a plurality of third LEDs. The plurality of third LEDs may be edge-emitting LEDs, and each singulated third dies may further comprise a plurality of third waveguides. At least one replacement third die may be disposed to overlap at least one singulated third die.

A second general aspect includes a method of forming a display device. The method comprises providing a plurality of singulated dies, each singulated die comprising a plurality of LEDs. The method further comprises attaching the plurality of singulated dies to a substrate (e.g., backplane, TFT backplane, a-Si TFT backplane, silicon backplane, any suitable backplane).

In some embodiments, the singulated dies are singulated first dies, and the LEDs are first LEDs. The method may further comprise providing a plurality of singulated second dies. Each singulated second die may comprise a plurality of second LEDs. The method may further comprise attaching the singulated second dies to overlay the singulated first dies.

In some embodiments, the method may further comprise attaching at least one replacement die to overlap at least one singulated die. In some embodiments, the method may further comprise attaching at least one replacement first die and at least one replacement second die to overlap at least one singulated first die and at least one singulated second die.

In some embodiments, the singulated dies are singulated first dies, and the LEDs are first LEDs. The method may further comprise providing a plurality of singulated second dies, each singulated second die comprising a plurality of second LEDs. The method may further comprise providing a plurality of singulated third dies, each singulated third die comprising a plurality of third LEDs. The method may further comprise attaching the singulated third dies to overlay the singulated first dies, and attaching the singulated second dies to overlay the singulated third dies. Each die may be directly hybrid bonded to a vertically adjacent die without use of an intervening adhesive.

In some embodiments, the plurality of singulated dies comprises a plurality of first singulated dies and second singulated dies. Each first singulated die may comprise a plurality of first LEDs and first waveguides. Each second singulated die may comprise a plurality of second LEDs and second waveguides. Attaching the plurality of singulated dies to the backplane may comprise directly hybrid bonding first singulated dies to second singulated dies to form stacked dies, and directly hybrid bonding the stacked dies to the backplane. Light emitted from the first LEDs may be guided by the first waveguides through the second waveguides towards the viewing surface of the display device.

In some embodiments, the singulated dies are singulated stacked dies, each singulated stacked die comprising a singulated first die and a singulated second die. The singulated first die may comprise a plurality of first LEDs and first waveguides, and the singulated second die may comprise a plurality of second LEDs and second waveguides. Providing the plurality of singulated dies may comprise hybrid bonding a first wafer and a second wafer to form stacked wafers and dicing the stacked wafers to form stacked dies. Attaching the plurality of singulated dies to the backplane may comprise directly hybrid bonding the plurality of singulated stacked dies to the backplane. Light emitted from the first LEDs may be guided by the first waveguides through the second waveguides towards the viewing surface of the display device.

In some embodiments, the display device may comprise dies that are singulated from any suitable substrate or wafer. A substrate may be a reconstituted wafer comprising LEDs (e.g., surface emitting LEDs) and/or optical elements (e.g., mirrors, waveguides, etc.). The dies may be attached to any suitable substrate (e.g., backplane, silicon or TFT backplane, a-Si TFT backplane, any suitable backplane, reconstituted substrate with singulated control device, etc.).

In some embodiments, the methods, systems, and apparatus (e.g., displays) described throughout the present disclosure may be applied to any suitable applications such as photo emissive applications (e.g., LED displays, laser arrays, vertical-external-cavity surface-emitting laser (VECSEL) arrays, etc.) photo sensitive applications (e.g., visible imager, short-wave infrared (SWIR) imager, near-infrared (NIR) imager, ultraviolet (UV) imager, etc.) or a combination thereof (e.g., light emitting and/or photo detection application, optical communications application, etc.).

### BRIEF DESCRIPTION OF THE DRAWINGS

The above and other objects and advantages of the disclosure will be apparent upon consideration of the following detailed description, taken in conjunction with the accompanying drawings, in which:

FIGS. 1A-1G show schematic example views of display devices, in accordance with embodiments of the present disclosure;

FIGS. 2A-2B shows schematic example views of display devices, in accordance with embodiments of the present disclosure;

FIGS. 3A-3C schematically illustrate aspects of methods for forming display devices, in accordance with embodiments of the present disclosure;

FIG. 4 schematically illustrates aspects of a method of forming a layer of a display device, according to some embodiments;

FIG. 5 schematically illustrates examples of inter-pixel deep trench isolations (DTI) in a display device, according to some embodiments;

FIGS. 6A-6B schematically illustrate hybrid bonding, according to some embodiments;

FIG. 7A-7B schematically illustrates an example cross-section of a pixel configuration in a display device, according to some embodiments;

FIGS. 8A-8B schematically illustrate example views of a pixel configuration in a display device, according to some embodiments;

FIGS. 9A-9D schematically illustrate example views of a pixel configuration in a display device, according to some embodiments; and

FIG. 10 schematically illustrates aspects of a method of forming a layer of a display device, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein may provide for improved (e.g., more efficient or high-volume) manufacturing of displays (e.g., display devices, LED displays, LED display devices, micro-LED displays, micro-LED display devices) using singulated dies with plurality of LEDs. Advantageously, forming a display from singulated dies, each singulated die comprising a plurality of LEDs, may enable efficient fabrication of an integrated color pixel display from different wafers.

The integration of microLED technology in displays may offer significant benefits in terms of resolution, energy efficiency, brightness, and overall display performance. The ability to precisely control each microLED may allow for better luminous flux with a higher dynamic range and a broader spectrum of colors, leading to more vibrant, bright, and lifelike images, which may be beneficial for applications requiring high-definition visuals, such as advanced televisions, smartphones, wearable devices, automotives, and virtual/augmented reality devices. Additionally, the energy efficiency of microLEDs may translate into longer battery life for portable devices and lower power consumption for larger displays. The versatility of microLED technology extends to the potential for flexible and transparent displays, opening new avenues for innovative design and application in various fields, ranging from consumer electronics to specialized industrial and medical equipment. MicroLED displays may have higher brightness, increased power efficiency, longer lifetime, more durability, and may be more suitable for stretchable and transparent display applications over light-crystal displays (LCD) or organic light emitting diode (OLED) displays.

However, microLED displays may be costly to fabricate and may have time-consuming manufacturing methods such as robot-aided pick-and-place processes used to transfer microLED chips from LED wafer(s) to a display substrate. As an example, a microLED ultra-high density (UHD) 4K RGB (red, green, blue) display may comprise about or at least 25 million microLEDs (e.g., about 8.3 million pixels with each pixel having at least a red microLED, a blue microLED, and a green microLED), and a die bonding machine may transfer between 5 to 10 microLEDs per second, taking approximately 700 hours to transfer 25 million microLED chips for a single display. Accordingly, there exists a need in the art for improved microLED displays with a streamlined mass transfer processes and the methods of manufacturing the same.

LEDs may be fabricated at a first wafer (e.g., 150 mm wafers) and integration with silicon at a second wafer (e.g., 300 mm wafer) may be challenging. Reconstituting LED and silicon separately may help integration and assembly. Different colored LEDs may be fabricated on different wafers (e.g., red LED wafer, green LED wafer, blue LED wafer), singulated (e.g., diced) into individual LEDs (e.g., red LEDs, green LEDs, and blue LEDs), and then transferred (e.g., picked and placed, bonded) onto a display backplane (e.g., transistor matrix, silicon or TFT backplane, amorphous silicon (a-Si) TFT backplane(s), any suitable backplane) to form a display.

In some approaches, R, G, and B wafers may be patterned and vertically stacked. For example, a wafer of patterned blue LEDs may be stacked on top of a wafer of patterned green LEDs, and the wafer of patterned green LEDs may be stacked on top of a wafer of patterned red LEDs. However, the vertically stacked wafers may have LEDs (e.g., surface emitting LEDs) that are overlapping when emitting light, which may be inefficient considering brightness per unit area. The LEDs or substrate may not be transparent to light, and vertically overlapping LEDs may block the light from LEDs underneath. For example, a red LED on bottom may only emit light in areas not occupied by overlapping green and blue LED, and green LED in the intermediate position may only emit light in areas not occupied by overlapping blue LED.

In some approaches, R, G, and B wafers may be reconstituted and vertically stacked. For example, each R, G, and B wafer may be singulated and reconstituted into corresponding R, G, and B reconstituted substrates (e.g., each reconstituted substrate may comprise a plurality of single color LEDs). In the vertically stacked reconstituted substrates, the LEDs may be offset so they are not vertically overlapping and do not block light from LEDs underneath. However, reconstituting and vertically stacking R, G, and B wafers may result in inefficient use of a pixel area. For example, each R, G, and B LED (e.g., surface-emitting LEDs) may have about 30% or less or about 20-25% or less in fill factor (e.g., active area of each LED to a pixel area or footprint). Having a lower fill factor may effectively reduce the brightness of the pixel.

In some approaches, displays (e.g., microLED displays) may be formed via monochromatic wafer stacking without singulation (e.g., singulating each LED). Entire wafers or dies a size of the display may be stacked, and each wafer or die may be capable of emitting a single color to form full-color displays. For an RGB display, a wafer of each color LED may be stacked on a backplane (e.g., TFT backplane, a-Si TFT backplane, silicon backplane, any suitable backplane). The wafers or substrates (e.g., R, G, B LED wafers, TFT, a-Si TFT backplanes or silicon backplane or any suitable backplane) may be singulated before or after bonding, to the size of the display (e.g., 6 mm×6 mm, any suitable size of a microLED display, etc.). However, defects in any single wafer can adversely affect the performance of the entire stacked assembly, and may have decreased device reliability and lower production yield. A microLED display formed by stacking wafers or dies the size of the display may have issues due to compound yield of stacked wafers.

Advantageously, the displays or display devices (e.g., microLED displays) and manufacturing methods described herein may provide for reduced manufacturing costs and manufacturing time compared to conventional pick-and-place manufacturing. Use of edge-emitting LEDs and corresponding waveguides may increase a size of LEDs in a pixel, thereby increasing the brightness emitted from each pixel. Embodiments in the present disclosure may enable advantages of monochromatic wafer stacking with pick-and-place techniques to repair blocks of pixels to enhance production yield and maintain high-quality display characteristics. Use of singulated chips comprising a plurality of LEDs may reduce the number of LEDs to be transferred using pick-and-place and increase efficiency of forming a display.

A size of a pixel for a display may vary depending on the application—about 5 microns or less than about 5 microns, less than about 10 microns, or about 5-10 microns for augmented reality/virtual reality (AR/VR) or mixed reality (MR) applications, about 30-50 microns for watches, about 40-60 microns or about 50-70 microns for cellphones, about 300-400 microns or about 350 microns for computer monitors and screens, about 500-1000 microns or greater than about 0.5 mm for televisions. The size of the source LED occupying the pixel may not match the size of the pixel itself. Light emitted from a small LED can fill all of the pixel area of a large pixel and help create a continuous image. The ratio of pixel size to LED size can range from about 1.5 to 3 in AR/VR or MR applications (e.g., pixel size is about 1.5× LED size to about 3× LED size) to over 100 (e.g., pixel size greater than about 100× LED size) in a television application. The smaller the ratio (e.g., area of pixel to area of LED), the larger the LED fill factor, and more light would be output. A larger LED fill factor indicates higher brightness requirement of the application. Different applications have varying luminous flux density requirement (e.g., brightness requirement). While AR/VR applications require extremely bright light so the projected images may be visible in extreme conditions (e.g., bright daylight), brightness requirements may be less stringent for other applications such as monitors and TVs in which the screens which have a larger viewing distance (e.g., are comparatively far away from an eye of a viewer). In some embodiments, a pixel comprises a plurality of source LEDs (e.g., an RGB pixel comprises 3 LEDs per pixel, an RGBG (red, green, blue, green) pixel comprises four LEDs per pixel), and a control circuit may be shared by several pixels.

The shorter the distance between the screen and viewer (e.g., an eye of a viewer) in an application, the smaller the pixel size requirement to provide a continuous image without a visible gap between the neighboring pixels. In AR/VR or MR applications, where a display may be about 1-2 cm from an eye of a viewer, pixel sizes may be typically less than 5 microns, and there may be a challenge to achieve high pixel density and to ensure uniformity and brightness of pixels for an immersive visual experience. Such applications may require smaller pixels (e.g. <5-10 um) and larger fill factor. The embodiments herein describe approaches which may enhance the density and uniformity of the pixels and/or improve the light emission efficiency. In television applications where pixel sizes can be greater than 0.5 mm (e.g., the screen is typically several feet away from the eye of a viewer; hence larger pixel and smaller LED fill factor would work), a stacked LED structure may be used for larger pixel requirements. In some embodiments, a pixel may include additional LEDs (e.g., other than RGB, such as white, cyan, magenta, etc.) to achieve an enhanced color gamut beyond the standard RGB and/or to add more light emission to improve brightness.

In some embodiments, dielectrics specifically tuned to certain color spectrums may be used within the optical path of the display for improved efficiency. Suitable materials for these dielectrics may include polystyrene, cyclic olefin polymer/cyclic olefin copolymers, polycarbonate, PMMA (Acrylic), or Ultraviolet Acrylic. These materials are known for their high transmission in the visible spectrum, which is relevant for improved efficiency and functionality of an RGB display.

As described below, semiconductor substrates, display substrates, or micro-LED display substrates herein generally have a “device side,” e.g., the side on which semiconductor device elements are fabricated, such as transistors, resistors, capacitors, micro-LEDs, driver circuits, and interconnects, and a “backside” that is opposite the device side. The term “active side” or “display surface” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

In some embodiments, the term “substrate” herein refers to an element of a device made of silicon or other semiconductor materials. Alternatively, or additionally, the substrate includes other semiconductor materials such as germanium, gallium arsenic, or other suitable semiconductor materials. In some embodiments, substrate may further include other features such as various doped regions, a buried layer, and/or an epitaxy layer. Moreover, in some embodiments, substrate is made of an alloy semiconductor such as silicon germanium, silicon germanium carbide, gallium arsenic phosphide, or gallium indium phosphide. Furthermore, the substrate may be a semiconductor on insulator such as silicon on insulator (SOI) or silicon on sapphire.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

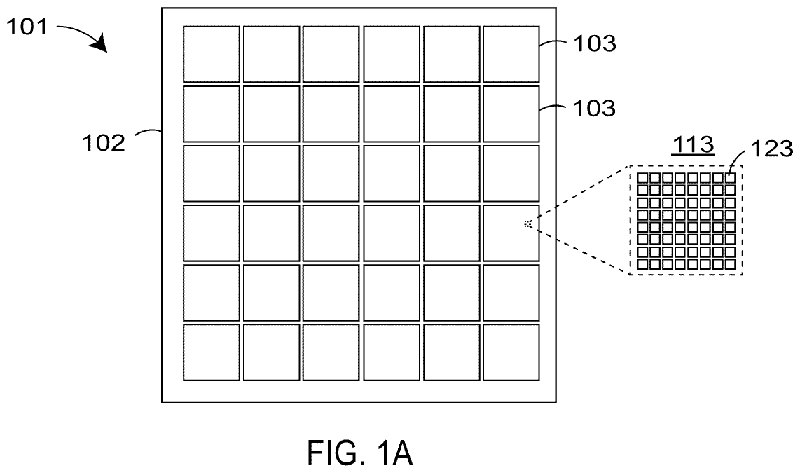

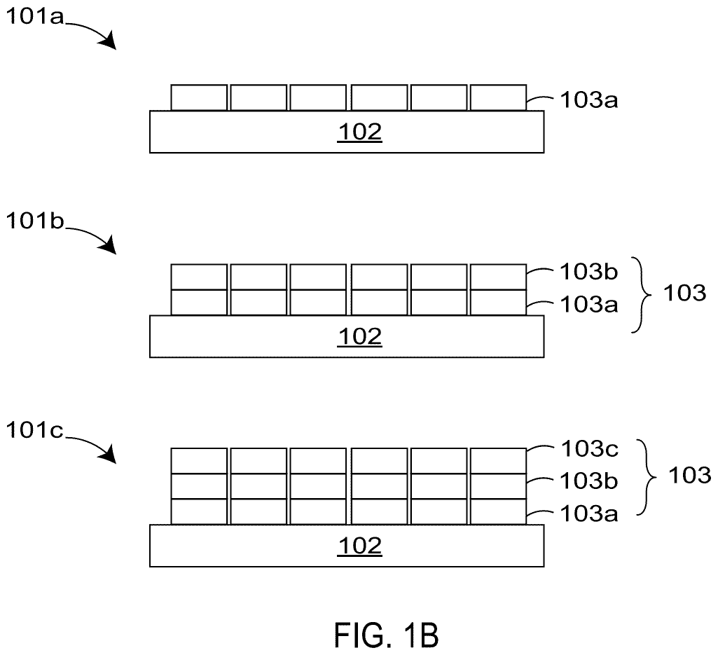

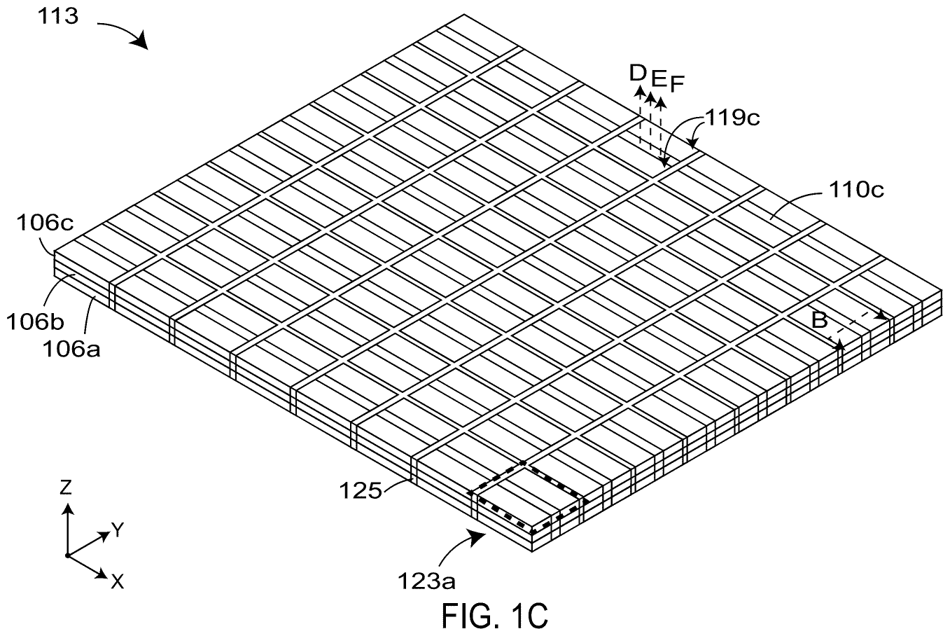

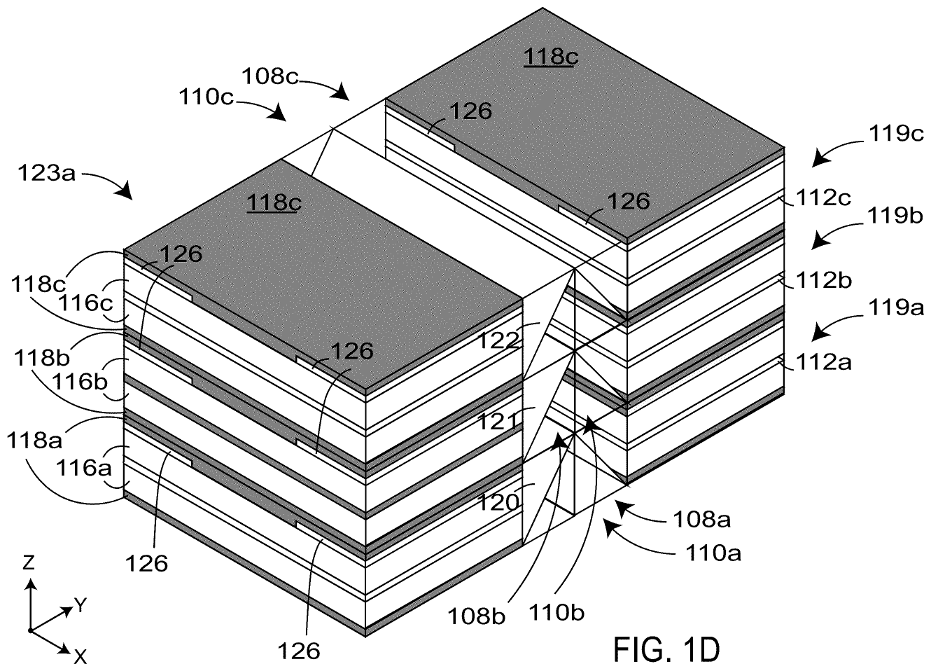

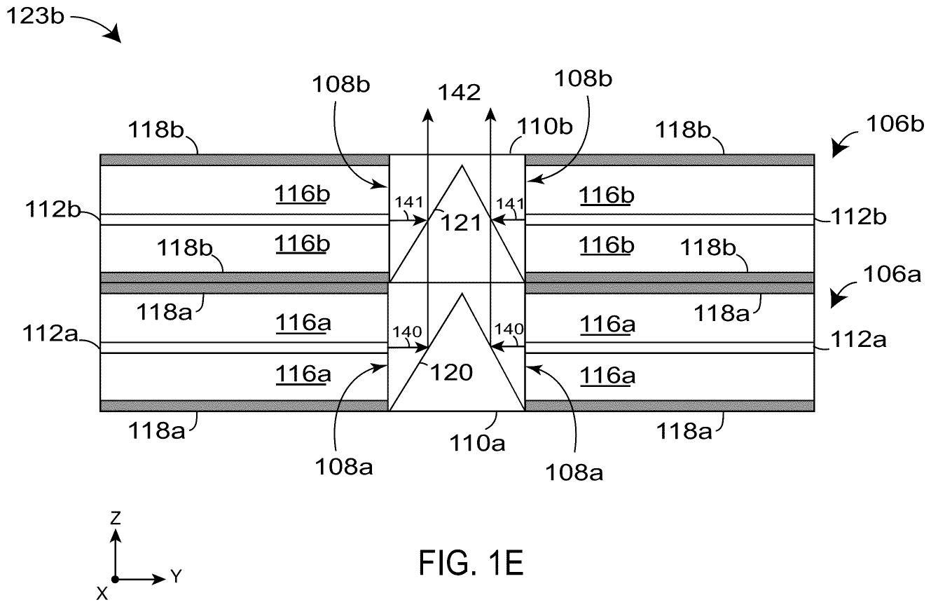

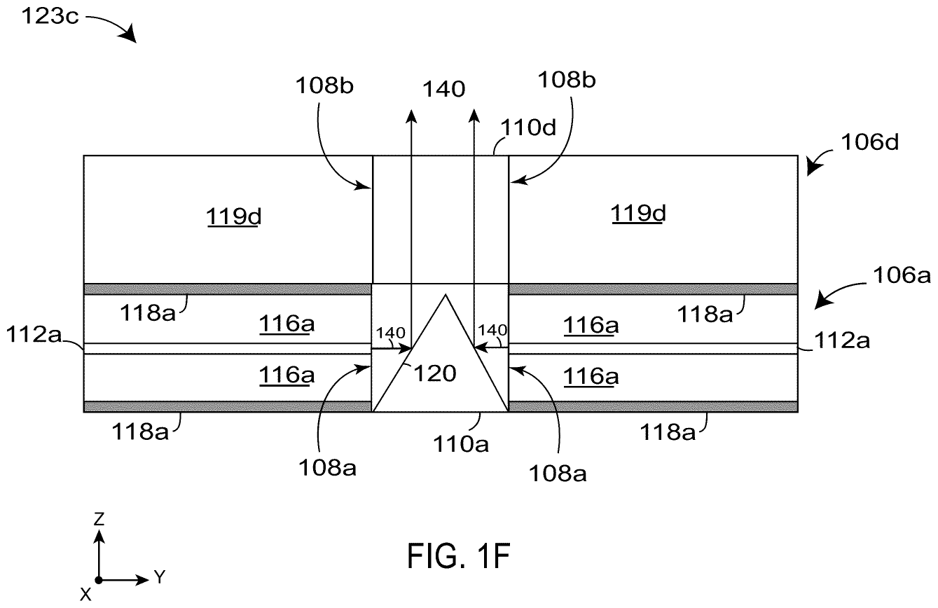

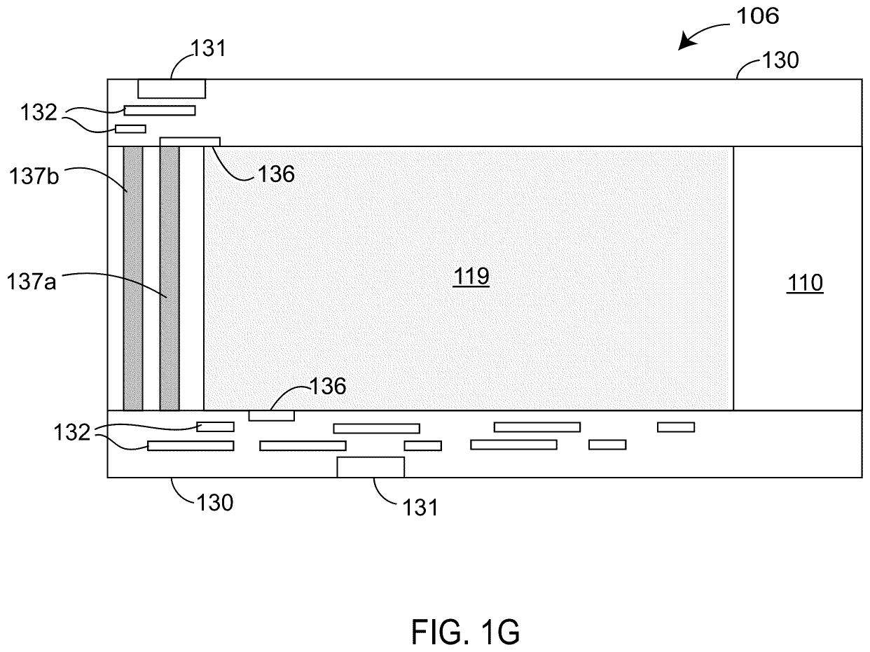

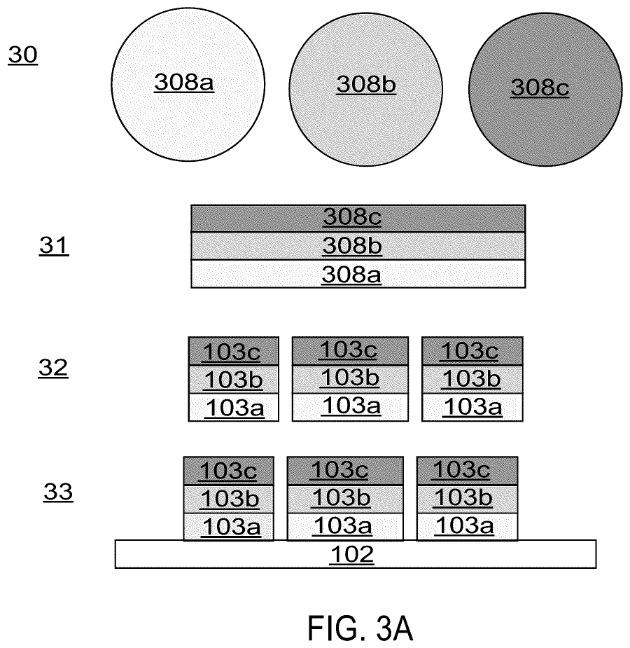

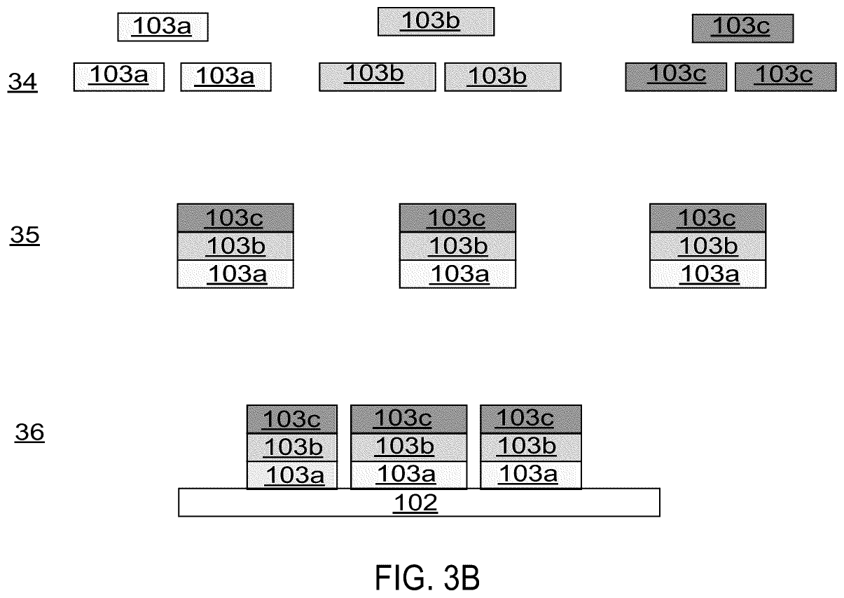

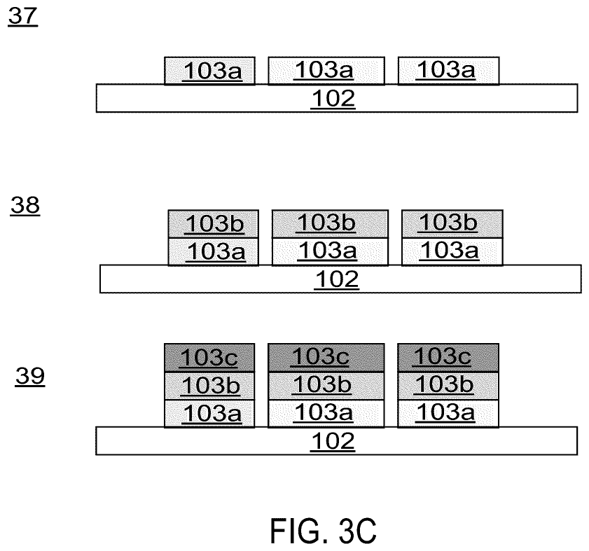

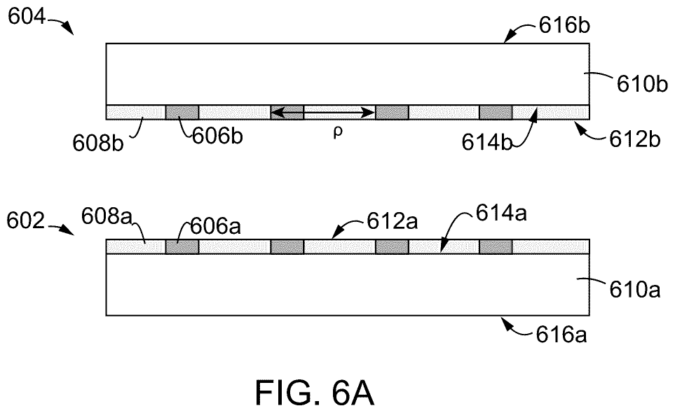

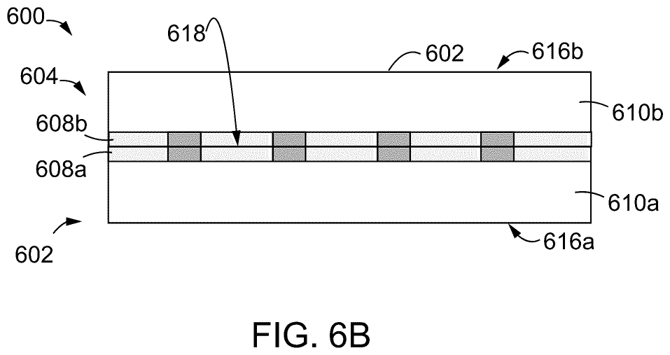

In some embodiments, the display (e.g., display 101 of FIG. 1A or any suitable display described throughout the present disclosure) may be a microLED display and comprise microLEDs, with sizes equal to or less than about 100 microns, 50 microns, or 5 microns. FIGS. 3-5 shows schematic example methods of forming a display device (e.g., display 101 of FIG. 1A) and may be applied to forming any suitable display described throughout the present disclosure. FIGS. 6A-6B illustrate a hybrid bonding method for bonding substrates (e.g., substrates comprising LEDs to substrates comprising LEDs, substrates comprising LEDs to substrates comprising control devices and/or LEDs).

In some embodiments, the display may be an LED display and comprise LEDs greater than about 500 microns in size or greater than about 100 microns in size. In some embodiments, the methods, systems, and apparatus (e.g., display) described throughout the present disclosure may be applied to any suitable applications such as photo emissive applications (e.g., LED displays, laser arrays, vertical-external-cavity surface-emitting laser (VECSEL) arrays, etc.) photo sensitive applications (e.g., visible imager, short-wave infrared (SWIR) imager, near-infrared (NIR) imager, ultraviolet (UV) imager, etc.) or a combination thereof (e.g., light emitting and/or photo detection application, optical communications application, etc.).

A display may comprise any suitable number of pixels (e.g., one or more pixels, a plurality of pixels). Although a display may show a specific number of pixels, in some embodiments the display may comprise any suitable number of pixels (e.g., hundreds, thousands, millions, 1 megapixel (MP, one million pixels), 4 MP, 8 MP, 50 MP, 100 MP, etc.) in any suitable arrangement of pixels (e.g., arranged in an XY grid, etc.).

A pixel may comprise any suitable number, shape, and color of sub-pixels or LEDs (e.g., one, two, three or more LEDs). Although a pixel may show a specific number of sub-pixels, in some embodiments the pixel may have any suitable number of sub-pixels or LEDs (e.g., one, two, four, five or more, etc.). Although the sub-pixels or LEDs are shown as similarly shaped rectangles, in some embodiments the sub-pixels or LEDs may be of any suitable shape. In certain embodiments, advancements in color conversion layers (e.g., colored phosphors, quantum dot layers, etc.) may permit the addition of a fourth color, like a green variant or cyan, to enhance the color gamut. In some embodiments, a pixel may comprise three sub-pixels (e.g., red sub-pixel, blue sub-pixel, and green sub-pixel). In some embodiments, a pixel may comprise four sub-pixels comprising a red LED, a blue LED, and two green LEDs. In some embodiments, LEDs of a pixel may also be electronically connected to a control device (e.g., integrated circuit, readout integrated circuits, etc.).

In some embodiments, the term “die” may refer to a physically separated piece from a wafer or substrate. In some embodiments, the term “die” may refer to a single unit or circuit on a wafer such as an LED. In some embodiments, the term “block” may refer a physically separated piece from a wafer or substrate comprising a plurality of unsingulated dies.

FIG. 1A schematically illustrates a top-down view of a display device or display 101, in accordance with some embodiments of the present disclosure. The display 101 comprises a plurality of blocks or dies 103 disposed on a substrate 102 (e.g., backplane, TFT backplane, a-Si TFT backplane, silicon backplane, or any suitable backplane). Although FIG. 1A shows a 6×6 array of blocks or dies 103 or thirty-six blocks or dies 103, the display may comprise any suitable number of blocks or dies (e.g., 2, 4, 25, 100, 1000, 10000 or more dies, etc.) in any suitable arrangement (e.g., 1×2, 2×2, 5×5, 10×10, 100×100 array of dies, etc.). Each block or die 103 may comprise one or more layers of LEDs or pixels that are non-singulated (e.g., not diced and/or physically separated from a bulk material or base substrate the LEDs are disposed in) and independently operational. The dotted box 113 shows a zoomed-in portion of a block or die 103 comprising a plurality of pixels 123 (e.g., 8×8 or sixty-four pixels 123). A block or die 103 may comprise any suitable number of pixels (e.g., about 10,000 pixels, 100,000 pixels, less than or more than 10,000 pixels, 100,000 pixels, etc. with each pixel being an independently operational LED or one or more independently operational LEDs).

Each pixel 123 may be about 1 micron in size, about 1 to 100 microns in size, less than about 100 microns, 50 microns, 10 microns, 5 microns, or 3 microns in size. Die 103 may be any suitable shape (e.g., square, rectangular, hexagonal, etc.) and any suitable size (e.g., 100 microns×100 microns, or a side greater or less than 100 microns in size). A display 101 may be efficiently formed using pick and place of larger dies comprising a plurality of pixels or sub-pixels per die (e.g., more than about 100,000, about 10,000 LEDs per die), compared to using pick and place of individual LEDs (e.g., single LED per die).

In some embodiments, substrate 102 may be a wafer (e.g., control or controller device wafer, device wafer, ROIC wafer, or a full wafer). In some embodiments, the substrate 102 may be a reconstituted substrate comprising a plurality of singulated control devices (e.g., dies, chips) embedded or disposed in a dielectric layer or material. Each control device may be electrically connected to one or more pixels or LEDs. In some embodiments, each die 103 has a microLED driver and/or a sensor. In some embodiments, the plurality of LEDs or pixels 123 from each die 103 may be electrically coupled to a microLED driver (e.g., control device) in substrate 102. Each pixel or LED may be individually controlled by the microLED driver. In some embodiments, the plurality of LEDs or pixels 123 from each die 103 may be electrically coupled to a sensor in substrate 102. In some embodiments the substrate 102 may be singulated (e.g., each die 103 is attached to a singulated backplane (e.g., singulated TFT backplane, a-Si TFT backplane, silicon backplane, etc.). Stacked dies including the singulated backplane may be transferred to and attached to a substrate to assemble the display 101.

In some embodiments, the display may be a microLED display of any suitable size (e.g., 6 mm×6 mm). A 6 mm×6 mm microLED display with 3 micron pixels may have about a 4 MP display resolution (e.g., 2000×2000 pixels). An RGB microLED display with 4 million pixels would have 4 million LEDs of each color (e.g., R, G, B) or 12 million LEDs or about 12 million LEDs of same color emission (e.g. one or two of red, green and blue), but different color filters.

In some embodiments, a microLED display may be formed by transferring a plurality of dies on a substrate (e.g., TFT backplane, a-Si TFT backplane, silicon backplane, etc.), each die comprising a plurality of non-singulated individually controllable LEDs. A die may comprise any suitable number of pixels (e.g., about 10,000 pixels, 100,000 pixels, etc.). For example, a method of forming a 6 mm×6 mm microLED display may include transferring thirty-six stacked dies, each stacked die having about 1 mm×1 mm footprint and including about 110,000 pixels (e.g., about 110,000 red LEDs, 110,000 blue LEDs, and 110,000 green LEDs) to a backplane (e.g., TFT backplane, a-Si TFT backplane, silicon backplane, any suitable backplane). The method transfers larger dies (e.g., 1 mm×1 mm) compared to forming a display with individually singulated LEDs. Larger dies (e.g., 1 mm in size) may be easier to handle than smaller dies (e.g., 1-3 microns in size), and transferring fewer dies may significantly reduce the time to form a display (e.g., transferring thirty-six stacked dies instead of millions or tens of millions of individually singulated LEDs). A spacing between adjacent stacked dies may be about 1 micron, less than about 1 micron, less than about 5 microns, etc. In some embodiments, spacing between adjacent stacked dies may be smaller than 20% of at least one of the sides of an individual pixel on either of the dies.

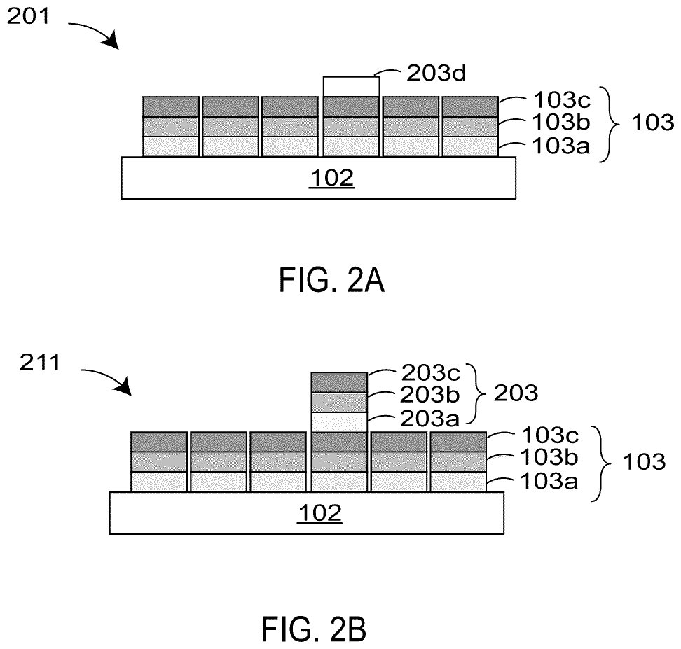

In some embodiments, forming a microLED display using pick and place (PNP) of larger dies onto a backplane (e.g., TFT backplane, a-Si TFT backplane, silicon backplane, any suitable backplane) may help enable higher yields. Larger dies may be tested and known good dies (e.g., dies with working LEDs, or dies with higher yields than other dies, or dies with yields higher than the minimum accepted yield (e.g. >80%, >90%, >95%, etc.)) may be selected to assemble the microLED display. A microLED display assembled using known good dies may have higher yields than a microLED display assembled using a single substrate or stacked substrates the size of the microLED display. A yield of the microLED display may be improved by increasing the number of dies that are stacked (e.g., as described in relation to FIGS. 2A-2B).

FIG. 1B schematically illustrates a cross-sectional side view of display devices or displays 101a, 101b, and 101c, in accordance with some embodiments of the present disclosure. Die 103 may comprise any suitable number of layers. Die 103 may be a single layer or die that is attached to substrate 102 (e.g., as shown in FIG. 1B as display 101a). Die 103 may be a stacked die comprising any suitable number of stacked layers or dies (e.g., 2, 3, 4 or more, etc.). Die 103 may be two stacked dies that are attached to substrate 102 (e.g., as shown in FIG. 1B as display 101b). Die 103 may be three stacked dies that are attached to substrate 102 (e.g., as shown in FIG. 1B as display 101c).

In some embodiments, display 101a may correspond to a monochromatic display. In such displays, one or more color filters or color filter layers (e.g. quantum dot (QD) color filters) may be disposed on the display. In some embodiments, display 101b may correspond to a two-color display. In some embodiments, display 101c may correspond to a color display, three-color display, or RGB display. In some embodiments, color filters (e.g. quantum dot layers) may be disposed on the plurality of pixels in the display.

Display device or display 101c comprises a plurality of stacked dies (e.g., die 103 comprises die 103a, die 103b, and die 103c) on a substrate 102. Die 103a may be in a bottom or first layer of the stack, the die 103b may be in an intermediate or second layer of the stack, and die 103c may be in a top or third layer of the stack. Each die 103a-c of the stacked die comprises a plurality of LEDs. Although three die are shown to be stacked in display 101c, any suitable number of dies may be stacked (e.g., 2 dies, 3 or more dies, etc.).

Each pixel 123 may comprise a plurality of stacked and aligned sub-pixels or LEDs of each die. Each LED or sub-pixel of a die (e.g., dies 103a-c) may be electrically connected to joined to a sub-pixel of an adjacent die (e.g., dies 103a-c) and coupled to a control device within the substrate 102.

In some embodiments, the display 101c may be an RGB display. Each die 103a, 103b, and 103c may be singulated from a wafer (e.g., red, green, or blue LED wafer). Each stacked die 103a-c may comprise a die from a red LED wafer, a die from a blue LED wafer, and a die from a green LED wafer that is stacked in any suitable order. For example, die 103a may comprise LEDs that emit red light, die 103b may comprise LEDs that emit green light, and die 103c may comprise LEDs that emit blue light. In some embodiments, die 103a may comprise LEDs that emit blue light, die 103b may comprise LEDs that emit green light, and die 103c may comprise LEDs that emit red light.

Each stacked die may have any suitable number of dies (e.g., 2, 3, 4, 5 or more), any suitable color combination (e.g., RGB, RGBG, etc.), and any suitable order of layers. The stacked dies in a display may all have a same configuration (e.g., same number of layers, color, order of layers). In some embodiments, the stacked dies may have a different configuration (e.g., at least one of the stacked dies in a display may have a different number of layers, color, order of layers).

In some embodiments, die 103a may be directly attached to a substrate 102 (e.g., backplane, silicon backplane, a-Si TFT backplane, TFT backplane, any suitable backplane). The die 103a may be hybrid bonded to the substrate 102. Direct hybrid bonds may be formed between the substrate 102 and the die 103a (e.g., direct bonding of conductive features or bond pads disposed in respective dielectric layers, and direct bonding of dielectric layers). Each die may be directly hybrid bonded to a vertically adjacent die without use of an intervening adhesive. For example, dies 103a and 106b may be directly hybrid bonded, and dies 103b and 103c may be directly hybrid bonded. Additional detail regarding hybrid bonds and hybrid bonding of substrates may be found in the present disclosure, e.g., at least at the description of FIGS. 6A and 6B. Additional detail regarding how dies 103a-c are stacked and/or attached to substrate 102 can be found in the description of FIGS. 3A-3C.

FIG. 1C schematically an isometric view of a portion of a stacked die of a display (e.g., an 8×8 array of pixels 123a on a stacked die of display 101c of FIG. 1B), according to some embodiments. FIG. 1C shows three multilayer stacks (e.g., layers, substrates, chips, dies): a first multilayer stack 106a, a second multilayer stack 106b, and a third multilayer stack 106c. A third multilayer stack 106c may be disposed on a second multilayer stack 106b, and the second multilayer stack 106b may be disposed on the first multilayer stack 106a. Each of the multilayer stacks 106a-c may be bonded (e.g., directly bonded, hybrid bonded) to an adjacent multilayer stack 106a-c. Although FIG. 1C depicts three multilayer stacks, there may be any suitable number of multilayer stacks (e.g., 1 multilayer stack, 2 multilayer stacks, 4 multilayer stacks, etc.). For example, display 101 may comprise one substrate (e.g., 1 multilayer stack) comprising a plurality of LEDs and corresponding waveguides, where each LED is capable of emitting light in a first direction towards a corresponding waveguide and the corresponding waveguide is capable of reflecting the emitted light in a second direction towards a viewing surface of the display. In some embodiments, each LED may emit light in a first direction towards an edge of a display (e.g., along the y-axis, in any suitable direction in an emission plane of the multilayer stack or x-y plane, or any suitable direction), and the corresponding waveguide may be capable of reflecting the emitted light in a second direction (e.g., along the z-axis, a direction orthogonal to the first direction or emission plane, any suitable direction different from the first direction or at an angle to the first direction or emission plane, etc.) towards a viewing surface of the display. A method of forming a display device having at least one multilayer stack (e.g., plurality of dies 103) may comprise attaching (e.g., direct bonding, hybrid bonding) a first substrate comprising LEDs capable of emitting light in a first direction towards an edge of the display device (e.g., plurality of dies 103a), where a viewing surface of the display device is in the second direction, to a second substrate comprising one or more control devices (e.g., substrate 102, backplane, TFT backplane, a-Si TFT backplane, silicon backplane, etc.) to electrically connect the LEDs to the one or more control devices. In some embodiments, the first substrate may be a multilayer stack, a plurality of singulated dies comprising a plurality of edge-emitting LEDs from a wafer of edge-emitting LEDs, etc.

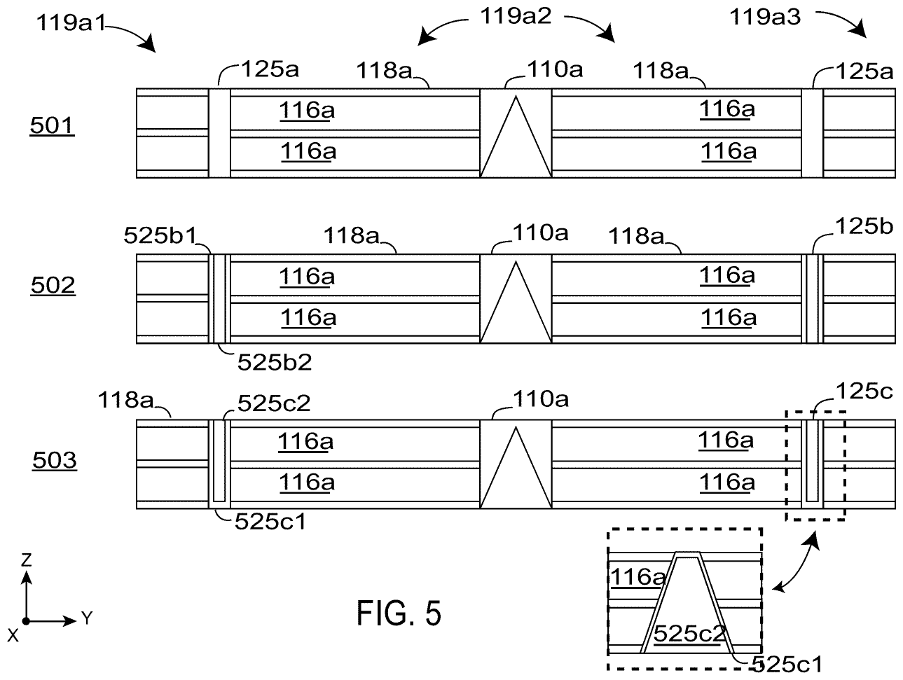

In some embodiments the multilayer stacks 106a-c are stacked or joined together by direct bonding or hybrid bonding. In some other embodiments, the multilayer stacks 106a-c are stacked or joined together by adhesives (e.g. epoxy, flip chip connections, etc.). In some other embodiments, the multilayer stacks 106a-c are stacked or joined together by metal to metal bonding (e.g. thermo-compression bonding). The dotted arrowed lines labeled as “B” represent the cross-section (Z-Y plane) of a pixel 123a further detailed in FIG. 1D without the DTI 125. The pixel 123a may include features such as the DTI 125. Examples of DTI are shown in more detail as various embodiments in FIG. 5. In some embodiments, a length and/or width of the pixel may be about 1 micron to 5 microns, 10 microns, or less than about 5 microns, less than about 10 microns. In some other examples, a length and/or width of the pixel may be less than about 50 microns (e.g. less than about 30 microns, less than about 20 microns, etc.). Although FIG. 1C shows three multilayer stacks (e.g., portion of three dies comprising a plurality edge emitting LEDs), in some embodiments a substrate comprising surface emitting LEDs may be in place of the top multilayer stack and the bottom two multilayer stacks may comprise edge emitting LEDs (e.g., top layer of surface-emitting LED 119d and waveguide 110d of FIG. 1F used in place edge-emitting LED 119c and waveguide 110c of top layer or multilayer stack 106c of FIG. 1C).

A display (e.g., display 101) may have any suitable number of pixels (e.g., 1 megapixel (MP, one million pixels), 4 MP, 8 MP, 50 MP, 100 MP) in any suitable arrangement (e.g., arranged in an XY grid, any suitable number dies, array of dies, etc.). Each pixel 123a may comprise three LEDs (e.g., LED 119a, LED 119b, and LED 119c). A pixel may comprise a portion or unit of an active area of a display device, and a plurality of pixels may be used to generate an image on the display device. A pixel 123a is bordered by the DTI 125 which may decrease optical cross talk or ‘light-bleed’ from light generated from neighboring or adjacent pixels. In some embodiments, a DTI for each multilayer stack 106a-c defines each LED 119a, LED 119b, and LED 119c. The DTI 125 may define (e.g., optically and electrically separates or provides separation of pixel areas or provides a gap between pixels 123a) each pixel of the display 101. In some embodiments, the DTI 125 comprises metal, polySi, reflective coating, oxide, dielectric or a combination thereof. Additional details of DTI configurations can be found in FIG. 5.

Each multilayer stack (e.g., first multilayer stack 106a, second multilayer stack 106b, and third multilayer stack 106c) may comprise a plurality of edge-emitting LEDs (e.g., edge-emitting LED 119a, edge-emitting LED 119b, edge-emitting LED 119c). A size of an edge-emitting LED may be about 5-10 microns. In some embodiments, the size or footprint of an edge-emitting LED may be about be less than 5 microns (e.g. <1 microns, <3 microns, etc.). In some embodiments, the size of an edge-emitting LED may be about be less than 50 microns (e.g. <15 microns, <30 microns, etc.). Each edge-emitting LED may comprise a respective active layer (e.g., active layer 112a, active layer 112b, active layer 112c). In the active layer, electron-hole recombination produces photons or light. The active layer may have a thickness of about 100 nm or less than about 100 nm. In some other embodiments, the active layer may have a thickness of about 200 nm or less, about 500 nm or less than about 1 micron. Disposed on top and bottom of each active layer or active region is respective cladding layers or lightguide layers (e.g., lightguide layers 116a, lightguide layers 116b, and lightguide layers 116c). The cladding layers or lightguide layers may sandwich a corresponding central active layer. For example, a central active layer 112a may be between a top and bottom lightguide layer 116a. A central active layer 112b may be between a top and bottom lightguide layer 116b. A central active layer 112c may be between a top and bottom lightguide layer 116c. The central active layer may be made using narrow bandgap material (e.g., InGaAs) bounded by wide bandgap cladding layers (e.g., p+ InGaAsP and n+ InP). The multiple layers may be deposited using epitaxial growth processes (e.g., molecular beam epitaxy (MBE), chemical vapor deposition (CVD), metal organic CVD (MOCVD), plasma enhanced CVD (PECVD), physical vapor deposition (PVD), etc.). The light produced in the active region may be spread into the transparent lightguide regions, effectively reducing the self-absorption of light in the active region. The lightguide layers collect light emitted from the active layer or active region and directs the collected light to the edges of the respective multilayer stack (e.g., through optical principle of total internal reflection (TIR)). The two cladding layers or lightguide layers may also help in confining injected electrons and holes into the middle layer (e.g., central active layer) and improving efficiency.

In some embodiments, as for a color display (e.g., RGB display), each of the three multilayer stacks 106a-c comprise active layers 112a-c that produce light different to one another (e.g., different range of wavelengths). For example, the first multilayer stack 106a of the display 101 may comprise an active layer 112a that produces red light, and some examples of these active layers include aluminum gallium arsenide (AlGaAs), aluminum gallium indium phosphide (AlGaInP), Gallium Arsenide Phosphide (GaAP), Gallium Phosphide (GaP) or any suitable material used to generate red light. The second multilayer stack 106b of the display 101 may comprise an active layer 112b that produces green light, and some examples of these active layers include Aluminium Gallium Indium Phosphide (AlGaInP), Aluminium Gallium Phosphide (AlGaP), indium gallium nitride (InGaN), gallium phosphide (GaP), or any suitable material used generate green light. The third multilayer stack 106c of the display 101 may comprise an active layer 112c that produces blue light, and some examples of these active layers may include indium gallium nitride (InGaN) or any suitable material used to generate blue light. In some embodiments, an active layer may comprise a phosphor.

In some embodiments, the active layer (e.g., active layer 112a, active layer 112b, or active layer 112c) may comprise InGaAs (or GaAs, AlGaAs, etc.) to produce near infrared light (NIR). Edge-emitting LEDs are typically used for long wave optical communication. Various forms of InGaAs, doped with other elements, may emit excitation wavelengths of 1.33 to 1.55 um. While InGaAs may be the active layer (for NIR applications), it may be bounded by wide bandgap layers (e.g., lightpipe or lightguide layer) such as p+ InGaAsP and n+ InP cladding layers. These two cladding layers (e.g., lightpipe or lightguide layers) help in confining injected electrons and holes into the active layer. The two cladding layers also help emitted photons to travel along the LED (e.g., x and y axis) through TIR and light may be emitted from the edge of the LED (e.g., an edge emitting LED). Edge emitting LEDs may be high brightness LEDs and may radiate less power to the air compared to surface emitting LED due to reabsorption and interfacial recombination.

The first multilayer stack 106a, second multilayer stack 106b, and third multilayer stack 106c each comprise a plurality of waveguides 110a, waveguides 110b, waveguides 110c, respectively. The waveguides 110a-c of the multilayer stacks 106a-c are centrally disposed in the pixel 123a. A size (e.g., width, length, and/or height) of the waveguides 110a-c may be about 500 nm. A width of the waveguide 110a, 110b, and 110c (e.g., along y-axis) may be about 100 nm, 200 nm, 500 nm, 1 micron, 3 micron, or less than about 100 nm, less than about 200 nm, less than about 500 nm, less than about 1 micron less than about 3 micron. In some embodiments, the thickness of the waveguides 110a-c may be less than about 25 microns, or less than about 15 microns, or less than about 10 microns, less than about 5 microns or less than about 3 microns thick. When the waveguides 110a-c of a respective multilayer stack 106a-c is centrally disposed in a pixel 123a, an edge-emitting LED 119a-c of the multilayer stack 106a-c may be separated into two portions. Each portion of the edge-emitting LED 119a-c may be optically positioned to emit light towards a respective waveguide 110a-c. The waveguides 110a-c include optical elements to direct light emitted from a respective edge-emitting LED 119a-c towards the surface of the display D, E, F. In some embodiments, each of the two separate portions of LED 119a may be communicatively coupled (e.g., have an electrical connection) to one independent integrated circuit (IC) to operate as a singular pixel 123a. For example, each portion of LED 119a may have a contact, connected to a connector and/or via(s), interconnect(s) and bond pad(s), as shown in FIG. 1G, to an IC in a layer below. In some embodiments, when an LED 119a is divided into two separate portions, it may be appreciated that each portion of LED 119a can be communicatively coupled to an independent integrated circuit (IC) (e.g. Readout IC or ROIC, controller chip, etc.) thereby allowing the system of the display to have control over color output. In some embodiments, the bottom most layer (e.g., substrate, multilayer stack 106a) as is directly bonded to hybrid bonded to ROIC chip. In some embodiments, bottom most layer (e.g., substrate, multilayer stack 106a) as is directly bonded to hybrid bonded to or flip chip attached to a backplane (e.g., silicon backplane, a-Si TFT backplane, TFT backplane, any suitable backplane). In some embodiments, the edge-emitting LEDs comprise optical coatings on the exterior surfaces of each the edge-emitting LEDs to prevent light leakage from the respective active layers. For example, the other side surfaces of the edge-emitting LEDs 119a-c that are not adjacent to a waveguide 110a-c may include a reflective surface to guide light to the waveguide 110a-c. FIG. 5 shows a multilayer stack (e.g., multilayer stack 106a) in which a metal layer, distributed Bragg reflective (DBR) coatings or other type of reflective surface (e.g., DTI 125a, outer portion 525b1 of DTI 125b, outer portion 525cl of DTI 125c) is adjacent to an edge of LEDs 119al and 119a2.

In some embodiments waveguides 110a-c may be referred to as reflecting blocks, reflector blocks, or reflector cubes. Each waveguide (e.g., waveguide 110a, waveguide 110b, and waveguide 110c) may be disposed in an opening (e.g., opening 108a, opening 108b, and opening 108c) of a respective multilayer stack (e.g., multilayer stack 106a, multilayer stack 106b, and multilayer stack 106c). Each waveguide 110a-c may be disposed in the center of each pixel 123a. Each waveguide 110a-c may comprise a metalized reflective film, distributed Bragg reflective (DBR) coatings or any other suitable reflecting surface, or reflecting material (e.g., reflector 120, reflector 121, and reflector 122) embedded or disposed in a material layer (e.g., oxide or dielectric material). The material layer may comprise a dielectric material (e.g. oxide material), an oxide fill, glass or other silica derived glasses, or any other suitable optically transparent material. The reflector 120-122 may guide or reflect light emitted from an active layer 112a-c of a corresponding edge-emitting LED 119a-c to the surface of the display 101.

In some embodiments, the reflectors 120-122 may be referred to as mirrors. The reflector (e.g., reflector 120, reflector 121, and reflector 122) may be a semi-transparent element, a beam splitting element or layer, or a partial mirror (e.g., a partially reflecting or partially transmitting mirror).

In some embodiments, the reflective surface or reflector 121 of the second multilayer stack 106b is capable of reflecting light emitted from the active layer 112b of the second multilayer stack 106b and transmitting light emitted from the active layer 112a of the first multilayer stack 106a. The reflective surface or reflector 121 may be a dichroic optical element. In some embodiments, the dichroic optical element may be a dichroic filter or dichroic filter coatings, interference filter, optical bandpass filter, etc. A dichroic filter may transmit light of some wavelengths while reflecting light of other wavelengths. In some embodiments, the dichroic optical element may be a dichroic mirror. A dichroic mirror may reflect light of some wavelengths while transmitting light of other wavelengths. The reflective surface or reflector 121 may be a plurality of thin films (e.g. alternating thin films) of varying materials of varying indices of refraction configured to allow for the transmission of the wavelength band emitted by the active layer 112a of the first multilayer stack 106a while reflecting the wavelength band emitted by the active layer 112b of the second multilayer stack 106b. For example, a dichroic filter may transmit light of the wavelength band emitted by the active layer 112a while reflecting the wavelength band emitted by active layer 112b. As another example, a dichroic mirror may reflect the wavelength band emitted by active layer 112b while transmitting light of the wavelength band emitted by active layer 112a.

In some embodiments, reflective surface or reflector 121 and reflective surface or reflector 122 may be manufactured using dichroic filters. In some embodiments, dichroic filters are multiple layers of dielectric thin films that transmit specific wavelengths of light while reflecting undesired wavelengths at a particular angle of incidence. To manufacture a dichroic filter, thin layers of alternating high and low index refraction materials are applied or formed on a suitable substrate (e.g. glass, oxide, etc.). Light coming into the filter at a specific angle comes in contact with the first index layer and some of the light is reflected and some of the light passes through based on its wavelength which is determined by the index layer. As light travels through these multiple alternating high and low index layers at different speeds, the reflected light either stays in phase (constructive interference) or is reduced by being out of phase (destructive interference) through phase shifts that narrow the final emitted light to a very specific wavelength band. The thickness of the index layers are responsible for the phase shifts and are specifically controlled as well as the number of layers applied to the glass surface to obtain the correct wavelength emitted from the filter. In some embodiments, the reflecting surfaces (e.g., reflectors 120,) and/or reflecting sidewalls of LEDs may be manufactured using metallized mirrors and may be created using a metallization process. The metallization process may involve the deposition and patterning of various metals on an active side of the substrate (e.g., multilayer stack). Metals used in the fabrication of mirrors (e.g., micro mirrors) include aluminum (Al), silver (Ag), gold (Au), chromium (Cr), and indium tin oxide (ITO) or a combination thereof. For example, a thin layer of aluminum may be deposited on a side of a substrate to form the reflector, reflective surface, or micro mirror. An aluminum layer may be deposited using physical vapor deposition (PVD) techniques such as sputtering or evaporation. The deposited aluminum layer may be patterned using photolithography and etching processes to define the reflecting surfaces or mirror structures.

In some embodiments, any of the multilayer stacks comprise an insulation layer 126. The insulation layer 126 may comprise an oxide, nitride, or other suitable material to provide spacing between the metallization layer and the light pipe and active layer. In some embodiments there are no insulating layers 126.

In some embodiments, the display device (e.g., display 101 or any suitable display mentioned in the present disclosure) may comprise vias, bond pads, interconnects, and integrated circuits (IC). In some embodiments, each pixel or sub-pixel may have a corresponding IC for driving the pixel (e.g. ROIC) and each pixel or sub-pixel may have an electrical connection to the corresponding IC. The bond pads, vias, and interconnects may connect and communicatively couple electrical components (e.g., contacts of LEDs) of the multilayer stack to integrated circuits (e.g., in a layer below) of a display device. Examples of vias, interconnects, and bond pads in a layer of a multilayer stack can be found in FIG. 1D and related description.

Each edge-emitting LED may be communicatively coupled to an independent integrated circuit (IC) to control the color output. In some embodiments, the edge-emitting LEDs of one pixel may be communicatively coupled to an independent integrated circuit (IC) to operate as a single pixel 123a. In some embodiments, a control device may be coupled to a plurality of pixels. In some embodiments, each multilayer stack 106a-c comprises a respective metallization layer (e.g., metallization layer 118a, metallization layer 118b, metallization layer 118c) disposed on the top and bottom of the multilayer stack or on the outside faces of the respective lightguide layers 116a-c (e.g., light pipe layers). In some embodiments, metallization layer 118a-c may be fabricated using copper, aluminum or transparent metal lines (e.g. transparent conductive oxide (TCO) such as ITO).

In some embodiments, the display (e.g., display 101 or any suitable display such as those mentioned in the present disclosure) is an RGB display and the active layer 112a is capable of emitting red light, the active layer 112b is capable of emitting green light, and the active layer 112c is capable of emitting blue light. In some embodiments, the display comprises one color or wavelength. In some embodiments, the display is capable of emitting light of two colors, or a combination thereof. In some embodiments, a display has one or two color emitters, and suitable filters may be applied to form an RGB display. Blue and ultraviolet (UV) light may excite phosphors that emit higher wavelengths, so it may be advantageous to position a blue edge-emitting LED on top of the display (e.g., active layer 112c emits blue light).

Between each the edge-emitting LEDs and respective waveguides may exist a plurality of optical layers. The optical layers may change a polarization of light, an amplitude of light, a direction of light, a dispersion of light, or a phase of light. The display (e.g., display 101 or any suitable display such as those mentioned in the present disclosure) may use any suitable combination of colors or any suitable stacked order of colors.

In some embodiments, the reflector blocks or reflector cubes are superimposed on one another (e.g., overlapping in a top down view) and may comprise reflecting elements to allow the transmission of light therebelow. For example, the openings 108a-c of each the multilayer stacks 106a-c are superimposed, and each respective waveguides 110a-c or reflecting blocks are superimposed. In some embodiments, the openings for each multilayer stack are not superimposed and may comprise reflector blocks or reflector cubes comprising a metal reflector.

In some embodiments each the respective reflector cubes or waveguides 110a-c are directly bonded to the neighboring reflecting block or waveguide 110a-c. In some embodiments each the respective reflector block or waveguides 110a-c are hybrid bonded to the neighboring reflecting block or waveguide 110a-c.

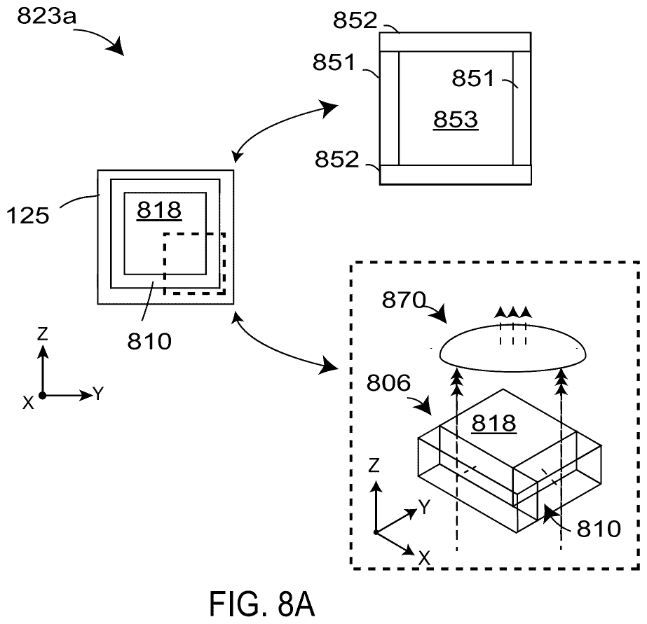

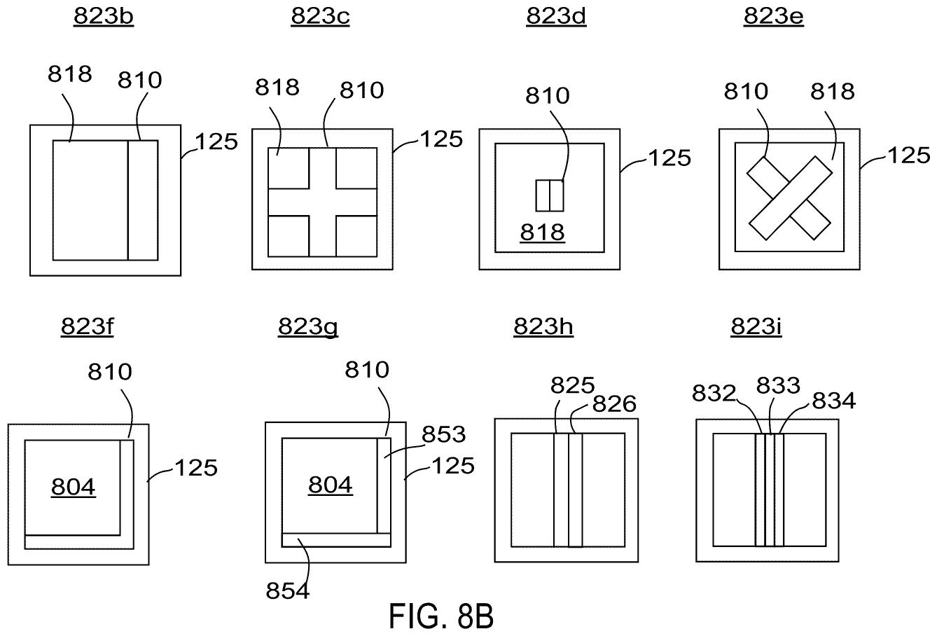

In some embodiments, the edge-emitting LEDs 119a-c comprise centrally located (per pixel) edge emission openings 108a-c and disposed in the openings 108a-c are reflector blocks or waveguides 110a-c. In display 101, each the respective waveguides 110a-c are superimposed. Although FIG. 1C shows a specific design for the aperture or edge emission openings 108a-c or placement of waveguides 110a-c, various designs may be used for aperture or edge emission openings 108a-c or placement of waveguides 110a-c. Additional details about design for the aperture or edge emission openings 108a-c or placement of waveguides 110a-c including various shapes (cross, line, square, etc.) can be found in FIGS. 8A-8B.

Although FIGS. 1B-1C shows an embodiment of a display device comprising three stacked multilayer stacks, in other embodiments a display device may comprise any suitable number of stacked multilayer stacks (e.g., two, three, four or more multilayer stacks) and any suitable type of active layers (e.g., use of any suitable active material, emitting light of any suitable color). For example, in some embodiments a display may comprise four multilayer stacks with a multilayer stack comprising LEDs to generate red light, a multilayer stack comprising LEDs to generate blue light, and two multilayer stacks comprising LEDs to generate green light. In some embodiments, the display may comprise a multilayer stack comprising LEDs to generate blue light, a multilayer stack comprising LEDs to generate green light, and a multilayer stack comprising LEDs to generate light with any suitable material (e.g., layer of quantum dots, etc.) that may be disposed on or near to an emissive layer (e.g., layer that generates blue or green light) to convert blue or green emitted light to red light.

FIG. 1E schematically illustrates an example cross-section of a pixel configuration in a display device, according to some embodiments. For example, FIG. 1E may show a pixel 123b of a display 101b that comprises at least two multilayer stacks (e.g., a first multilayer stack 106a and a second multilayer stack 106b). In some embodiments, the display 101b is similar to or the same as display 101c, except the top multilayer stack (e.g., multilayer stack 106c, plurality of dies 103c) is removed from the display 101c. The display 101b may have similar features to the display 101c described above, and therefore the description of similar features is omitted for brevity. The reflector 120 may guide or reflect light emitted from the active layer 112a to the surface of the display 101b. The reflector 121 may guide or reflect light emitted from the active layer 112a to the surface of the display 101b. The waveguide 110a may be a full reflector (e.g. metallized reflector). The waveguide 110b comprises an oxide or an optically tuned material to allow the transmission of the wavelengths emitted from both the active layer 112a of the first multilayer stack 106a and the active layer 112b of the second multilayer stack 106b. The first multilayer stack 106a may be direct bonded or hybrid bonded to the second multilayer stack 106b. In some other embodiments, the multilayer stacks 106a-b are stacked or joined together by adhesives (e.g. epoxy, flip chip connections, etc.). In some other embodiments, the multilayer stacks 106a-b are stacked or joined together by metal to metal bonding (e.g. thermo-compression bonding).

In some embodiments, the bottom multilayer stack (e.g., multilayer stack 106a) has an active layer 112a capable of emitting blue light (e.g., 380-500 nm). The emitted blue light 140 exits at the opening 108a of the edge-emitting LED, transmits though the material layer of the waveguide 110a, and is reflected by reflector 120 disposed in the waveguide 110a towards the surface of the display 101b. The top multilayer stack (e.g., multilayer stack 106b) comprises an active layer 112b capable of emitting green light (e.g., 495-570 nm). The emitted green light 141 exits at the opening 108b, transmits though the material layer of the waveguide 110b, and is reflected by reflector 121 (e.g., a dichroic filter, interference filter, optical bandpass filter, etc.) disposed in the waveguide 110b towards the surface of the display 101b. The blue light emitted from the bottom multilayer stack 106a transmits though the dichroic reflector 121 towards the surface of the display. Light 142 exiting a display surface may comprise at least a portion of the emitted blue light 140 and emitted green light 141. In this example, the pixel 123b generates green and blue light and a mixture in between.

FIG. 1F schematically illustrates an example cross-section of a pixel configuration in a display device, according to some embodiments. For example, FIG. 1F may show a pixel 123c of a display 101b. The display 101b comprises a substrate 106d (e.g. die) disposed on a multilayer stack (e.g., multilayer stack 106a). In some embodiments, the display device in FIG. 1F is similar to the display device in FIG. 1E except the substrate 106d is used in place of the multilayer stack 106b.

The substrate 106d may comprise a plurality of surface emitting LEDs 119d and light guides or waveguides 110d. The surface emitting LEDs may comprise a phosphor. The substrate 106d may comprise waveguides 110d (e.g., waveguide block comprising fill material or glass) disposed in openings of the substrate 106d. The waveguides 110d may be superimposed over the waveguides 110a of the multilayer stack 106a. The waveguides 110d may comprise optically tuned material that allows for the transmission of light emitted from the first multilayer stack 106a. The waveguide 110d may comprise a dielectric, an oxide, or a combination thereof optically tuned to allow for the transmission of light emitted by the active layer of the first multilayer stack 106a. In some embodiments, the substrate 106d is attached (e.g., directly bonded, hybrid bonded) to the multilayer stack 106a. The waveguide 110d may be directly bonded or hybrid bonded to the waveguide 110a.

In some embodiments, the substrate 106d may be applied to a display device or display 101c of FIG. 1B. For example, substrate 106d may be used in place of the multilayer stack 106c of display 101c. The waveguides 110d may comprise optically tuned material that allows for the transmission of light emitted from the first and second multilayer stacks 106a-b. The waveguides 110d may be superimposed over top of waveguides 110a-b of multilayer stacks 106a-b. The waveguide 110d comprises a dielectric, an oxide, or a combination thereof optically tuned to allow for the transmission of light emitted by the active layer of the first and second multilayer stacks 106a-b. In some embodiments, the substrate 106d is attached (e.g., directly bonded, hybrid bonded) to the multilayer stack 106b, and the multilayer stack 106b is attached (e.g., directly bonded, hybrid bonded) to the multilayer stack 106a. The waveguide 110d may be directly bonded or hybrid bonded to the waveguide 110b. The waveguide 110b may be directly bonded or hybrid bonded to the waveguide 110a.

FIG. 1G shows detailed features of a substrate 106 (e.g., die, multilayer stack 106a-c, etc.) comprising an LED 119 and waveguide 110 such as redistribution layers 130 comprising conductive features or bond pads 131, interconnects 132 that include conductive wiring and conductive vias, connectors 136, and vias 137a, 137b. The features shown in FIG. 1G may be applied to any suitable display described in embodiments of present disclosure. Although not explicitly shown in various embodiments of the display in the present disclosure, it will be understood that through substrate vias (TSVs) and/or bond pads (e.g., via and/or bond pads shown in FIG. 1G) may be applied to any suitable substrates or layers (e.g., dies 103a-c, substrate 102, etc.) as mentioned throughout the present disclosure to connect a top side to a bottom side of the substrates and layers for electrical connectivity of the stacked substrates. In some embodiments, LED 119 is a surface-emitting LED (e.g., LED 119d in FIG. 1F) with waveguide 110 (e.g., waveguide 110d of FIG. 1F). When LED 119 is a surface-emitting LED, there may be no conductive features or bond pads 131 and interconnects 132 above the LED, or there may be ones that are transparent to visible light or wavelength range of interest (e.g., emitted by an underlying surface emitting LED). In some embodiments, LED 119 is an edge-emitting LED (e.g., multilayer stack 106a-c) with waveguide 110 (e.g., waveguides 110a-c) of FIGS. 1D-1E. When LED 119 is an edge-emitting LED, there may be conductive features or bond pads 131 and interconnects 132 above the LED.

In some embodiments, the substrate 106 of FIG. 1G may include an interconnect layer or redistribution layer 130, such as a redistribution layer (RDL). Contacts or electrodes of an LED 119 may be electrically connected to conductive features (e.g., bond pads 131) via connectors 136 through interconnects 132 in the interconnect layer or redistribution layer 130. The bond pads 131 embedded in a dielectric layer can be hybrid bonded to bond pads of control device (e.g., a processor or controller, ROIC, etc.) embedded, in some embodiments, in the layer below what is shown in FIG. 1D. One or more vias 137a-b may be disposed in the substrate 106 and enable connection through the substrate 106. The bond pads 131, vias 137a-b, connectors 136, and interconnects 132 may comprise any suitable conductive material. For example, a conductive material may include metals such as copper or copper alloys, nickel, aluminum, or alloys, conductive oxide material such as indium tin oxide (ITO).

FIGS. 2A-2B shows schematic example views of display devices, in accordance with embodiments of the present disclosure. FIGS. 2A-2B shows a display device or display 201 and display 211 that is similar to display 101c of FIG. 1B except that a replacement die (e.g., die 203d, stacked die 203) is attached to a top of the display 101c to a die 103 (e.g., die stack, stacked dies 103a-c). In some embodiments, a display 101c may be reworked for yield improvement. For example, a die 103 of a plurality of dies 103 of display 101 may comprise at least one or more defective pixels. Each die 103 of a display 101 may be tested (e.g., after bonding to a substrate 102), and at least one die 103 may be determined to include at least one or more defective pixels. A replacement die (e.g., die 203d, stacked die 203) may cover the defective die 103 (e.g., stacked or overlapping vertically with the defective die).

In FIG. 2A, a replacement die 203d may be a single layer or die (e.g., die 103a, 103b, or 103c) to cover for a corresponding defective die 103a, 103b, or 103c. Die 203d may be a replacement die 103a to cover for defective die 103a. Die 203d may be a replacement die 103b to cover for defective die 103b. Die 203d may be a replacement die 103c to cover for defective die 103c. Die 203d may be directly bonded to die 103c of a display 101c to form display 201. Die 203c may be directly bonded to die 103c.

In FIG. 2B, a replacement die 203 comprises a plurality of stacked dies. The replacement die 203 comprises stacked dies 203a-c. Each die of the replacement die 203 may be directly hybrid bonded to an adjacent die (e.g., dies 203a-c). The replacement die 203 may be hybrid bonded to an existing die in the display 101c to form display 211. A die 203a may be directly hybrid bonded to die 103c. In some embodiments, stacked dies 203a-c may be bonded together before attached to the display 101c. In some embodiments, die 203a-c are sequentially attached to display 101c to form display 211. For example, die 203a may be attached to die 103c. Die 203b may be attached to die 203a, and die 203c may be attached to die 203b.

Although the FIGS. 2A-2B include a display 101c with three stacked dies on which a replacement LED is attached to form displays 201 and 211, a replacement die may be applied to any suitable display (e.g., display 101a, 101b, display comprising stacked dies with four or more stacked dies, etc.).

In some embodiments, the method may include hybrid bonding the first die and the second die to form a workpiece. Attaching the two or more dies to the backplane (e.g., TFT backplane, a-Si TFT backplane, silicon backplane, any suitable backplane) comprises hybrid bonding the workpiece to the backplane.

In some embodiments, the plurality of wafers further comprises a third wafer. Providing the plurality of wafer may comprise providing the first wafer, the second wafer, and the third wafer. The method further comprises hybrid bonding the first die of the first wafer, the second die of the second wafer, and a third die of the third wafer to form a workpiece. Attaching the two or more dies to the backplane may comprise hybrid bonding the workpiece to the backplane.

In some embodiments, attaching two or more dies to a backplane (e.g., TFT backplane, a-Si TFT backplane, silicon backplane, any suitable backplane) comprises hybrid bonding the first die to the backplane, and hybrid bonding the second die to the first die.

In some embodiments, the plurality of wafers further comprises providing a third wafer. Providing the plurality of wafer may comprise providing the first wafer, the second wafer, and the third wafer. Attaching the two or more dies to the backplane (e.g., TFT backplane, a-Si TFT backplane, silicon backplane, any suitable backplane) comprises hybrid bonding the first die to a backplane, and hybrid bonding the second die to the first die, and hybrid bonding a third die to the second die.

FIG. 3A shows a schematic example method of forming display device (e.g., display 101c), in accordance with embodiments of the present disclosure. In some embodiments, the method comprises providing a plurality of wafers (e.g., any suitable number of wafers, 2, 3, 4 or more), hybrid bonding the plurality of wafers to form bonded stacked wafers, and dicing the bonded stacked wafers to form singulated stacked dies. Each singulated stacked die comprises a plurality of LEDs from each wafer. The method further includes attaching the singulated stacked die to a backplane (e.g., TFT backplane, a-Si TFT backplane, silicon backplane, any suitable backplane). Attaching the singulated die to the backplane may comprise hybrid bonding.

At block 30, the method comprises providing a first wafer 308a, a second wafer 308b, and a third wafer 308c. Each wafer may be a red LED wafer, green LED wafer, blue LED wafer, epi wafer, or any suitable wafer or substrate.

At block 31, each wafer 308a-c may be stacked and bonded to an adjacent wafer 308a-c. In some embodiments, the wafers 308a-c may be directly hybrid bonded. For example the wafers 308a-c may be wafer to wafer or W2W bonded.

At block 32, the stacked and bonded wafers may be singulated into stacked dies. In some embodiments, bonded wafers 308a, 308b, and 308c may be singulated using processes such as laser ablation, mechanical sawing, or plasma dicing, or any other suitable dicing process. Each singulated stacked die may comprise a plurality of non-singulated individually controllable LEDs.

At block 33, the singulated stacked dies may be transferred to and attached (e.g., hybrid bonded) to a substrate 102 (e.g., a backplane). The stacked dies may be attached using hybrid bonding. The die stacks may be transferred using pick-and-place. Connections may be made to a transistor matrix that controls individual pixels. Although blocks 30-33 suggests bonding three LED wafers (e.g., singulated stacked dies from three stacked and bonded wafers) to a backplane to form a display, any of the displays 101a, 101b or 101c as depicted in FIG. 1B can be formed. For example one or more monochromatic wafers (e.g., one wafer, two stacked and bonded wafers, etc.) can be singulated into dies and stacked on a backplane (e.g., TFT backplane, a-Si TFT backplane, silicon backplane, any suitable backplane) and one or more color filters (e.g. QD color filter) may be disposed to effectively form a color display.

FIG. 3B shows a schematic example method of forming display device (e.g., display 101), in accordance with embodiments of the present disclosure. In some embodiments, the method comprises providing a plurality of wafers (e.g., 2, 3, 4 or more), and dicing each wafer of the plurality of wafers into dies. Each die comprises a plurality of LEDs. The method further includes attaching two or more dies (e.g., 2, 3, 4 or more dies) to a backplane (e.g., TFT backplane, a-Si TFT backplane, silicon backplane, any suitable backplane).

At block 34 the method comprises providing singulated dies 103a, 103b, and 103c. In some embodiments, each wafer 308a, 308b, and 308c may be singulated using processes such as laser ablation, mechanical sawing, or plasma dicing, or any other suitable dicing process. Each singulated die 103a-c may comprise a plurality of non-singulated individually controllable LEDs.

At block 35, the method comprises bonding a singulated die 103a, 103b, and 103c to each other to form stacked singulated dies 103. In some embodiments, the stacked singulated dies 103 may be bonded in any suitable order. The stacked singulated dies may be die to die or D2D bonded.

At block 36, the method includes attaching the stacked dies 103 to the substrate 102. In some embodiments, the stacked dies 103 may be hybrid bonded to the substrate 102. Although blocks 34-36 suggests bonding three LED dies (e.g., stacks of dies 103a-c) to a backplane (e.g., substrate 102) to form a display, any of the displays 101a, 101b or 101c as depicted in FIG. 1B can be formed. For example, one or more monochromatic die(s) (e.g., dies 103a, stacks of dies 103a-b), each comprising plurality of pixels, can be stacked on a backplane (e.g., TFT backplane, a-Si TFT backplane, silicon backplane, any suitable backplane, substrate 102) and one or more color filters (e.g., QD color filter) may be disposed on the die or one or more dies to effectively form a colored display.

FIG. 3C shows a schematic example method of forming display device (e.g., display 101), in accordance with embodiments of the present disclosure. In some embodiments, the block 37 continues from block 34.

At block 37, the method comprises attaching singulated dies 103a to substrate 102. The singulated dies 103a may be hybrid bonded to the substrate 102. In some embodiments, the display formed at block 37 is display 101a of FIG. 1B.

At block 38, the method includes attaching singulated dies 103b to the singulated dies 103a. The method may comprise hybrid bonding singulated dies 103b to singulated dies 103a. In some embodiments, the display formed at block 38 is display 101b of FIG. 1B.

At block 39, the method includes attaching singulated die 103c to the singulated dies 103b. The method may comprise hybrid bonding singulated dies 103c to singulated dies 103b. In some embodiments, the display formed at block 39 is display 101c of FIG. 1B.

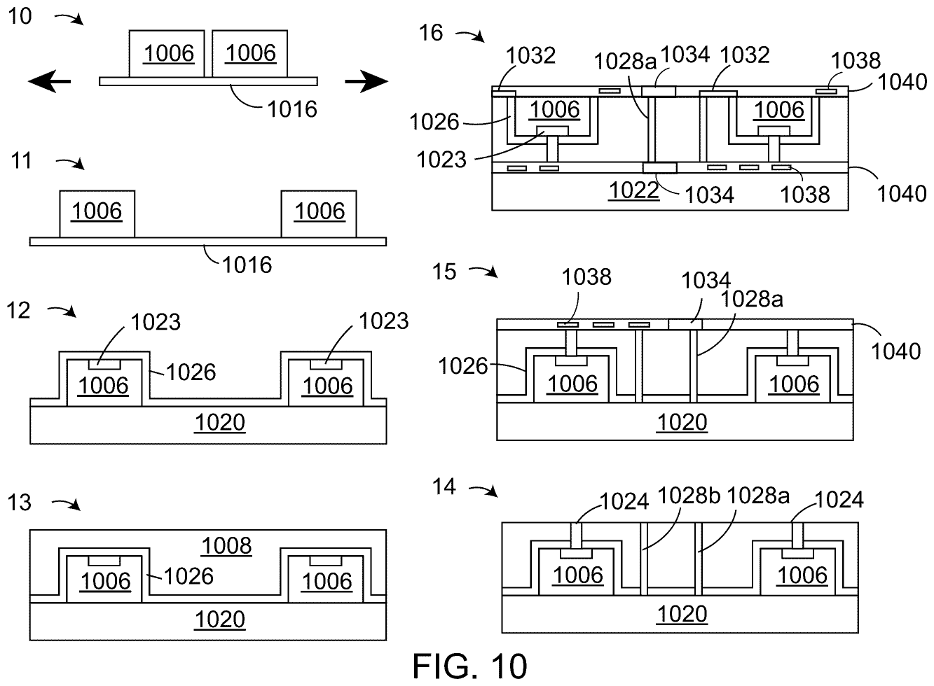

Although FIGS. 3A-3C show a substrate 102 that is non-singulated, in some embodiments the substrate 102 may be singulated. Each die 103 (e.g., dies 103a-c, or any combination thereof) may be attached to a singulated backplane (e.g., singulated TFT backplane, a-Si TFT backplane, silicon backplane, any suitable backplane) or die. The stacked dies including the singulated backplane die may be transferred to and attached to a substrate to assemble the display. The dies may be attached in any suitable order. For example, singulated backplane dies may be attached to a substrate, and dies 103 may be attached to the singulated backplane dies. Dies 103 may be stacked and bonded prior to being bonded to the singulated backplane dies, or sequentially stacked on the singulated backplane dies. In some other embodiments, the substrate 102 could be a reconstituted substrate (e.g., known good substrate dies are reconstituted into a wafer or substrate). A reconstituted substrate may comprise known good control device or processor dies. A reconstituted substrate may comprise singulated control devices and LED dies of at least one color (e.g., known good control devices and known good LED dies). In some other embodiments, the LED dies can be reconstituted to effectively form a reconstituted wafer or substrate. Any of dies 103a-c may be singulated from a reconstituted wafer or substrate of singulated LEDs (e.g., reconstituted substrate of LEDs 1006 as shown in FIG. 10). A reconstituted substrate of singulated LEDs may comprise singulated LEDs of at least one color (e.g., a monochromatic reconstituted wafer with single color LEDs, a reconstituted wafer with more than one color LEDs). In some embodiments the display devices can be formed using reconstituted wafer to wafer bonding, or reconstituted wafer to reconstituted wafer bonding or die to reconstituted wafer bonding. For example, a wafer 308c may be a reconstituted wafer bonded to wafer 308b, and a reconstituted wafer may be bonded to a wafer (e.g., at block 31 of FIG. 3A). In another example, both wafers 308c and 308b may be reconstituted wafers, and a reconstituted wafer may be bonded to a reconstituted wafer (e.g., at block 31 of FIG. 3A). As another example, a substrate 102 may be a reconstituted wafer (e.g., control device or processor dies and/or LED dies reconstituted in a wafer or substrate), and a die 103a may be bonded to a reconstituted wafer (e.g., die 103a to substrate 102 as shown in FIGS. 3A-3C).

In some embodiments, a micro-LED display may be constructed from singulated blocks containing multiple small independently operational dies. For example, these blocks may be derived from larger LED wafers, each comprising a plurality of non-singulated small dies hybrid bonded to a backplane (e.g., TFT backplane, a-Si TFT backplane, silicon backplane, any suitable backplane). The wafers may undergo a singulation process, resulting in larger dies composed of or comprising several smaller dies. These singulated blocks may then be integrated with uLED drivers and sensors, enabling the control and monitoring of individual dies. Given that each block can be tested, and faulty uLEDs can be replaced, this method may allow for the maintenance of high-quality display output. In some embodiments, each singulated block may contain one or more microLED drivers. In some embodiments, each singulated block may contain one or more sensors. In some embodiments, each singulated block may be tested, and a microLED may be attached in case of a microLED failure. In some embodiments, any suitable number of blocks may be used to form a micro-LED display of any suitable size or any suitable shape. In some embodiments, a block may comprise any suitable number of non-singulated small dies.

In some embodiments, a micro-LED display may be constructed using bonding of RGB singulated blocks to form stacked structures, followed by bonding of the stacked structures to a backplane (e.g., TFT backplane, a-Si TFT backplane, silicon backplane, any suitable backplane). For instance, the blocks comprising red, green, and blue LEDs may be bonded to form a stacked structure, which may then be attached to the backplane to create the display assembly or final display assembly. In scenarios where a die within the stack fails or is defective, the entire stack (e.g., a stacked RGB singulated block) may be replaced to ensure display functionality. The small and manageable size of the blocks may facilitate the replacement of bad or defective pixels through D2D bonding techniques, allowing for precise and efficient repairs. In some embodiments, only the defective die may be replaced. In some embodiments, if one color LED die is determined to be defective (e.g., blue LED die, die 103a), only that die may be replaced (e.g., replacement block of blue LEDs). In some embodiments, if a topmost die is surface emitting (e.g., red LED die, die 103c), a replacement block may include the topmost die (e.g., red LED die, 103c) and whichever die is found to be defective (e.g., blue LED die, die 103a) to maintain display quality. The replacement block of LEDs may include a replacement block red LEDs and replacement block of blue LEDs.

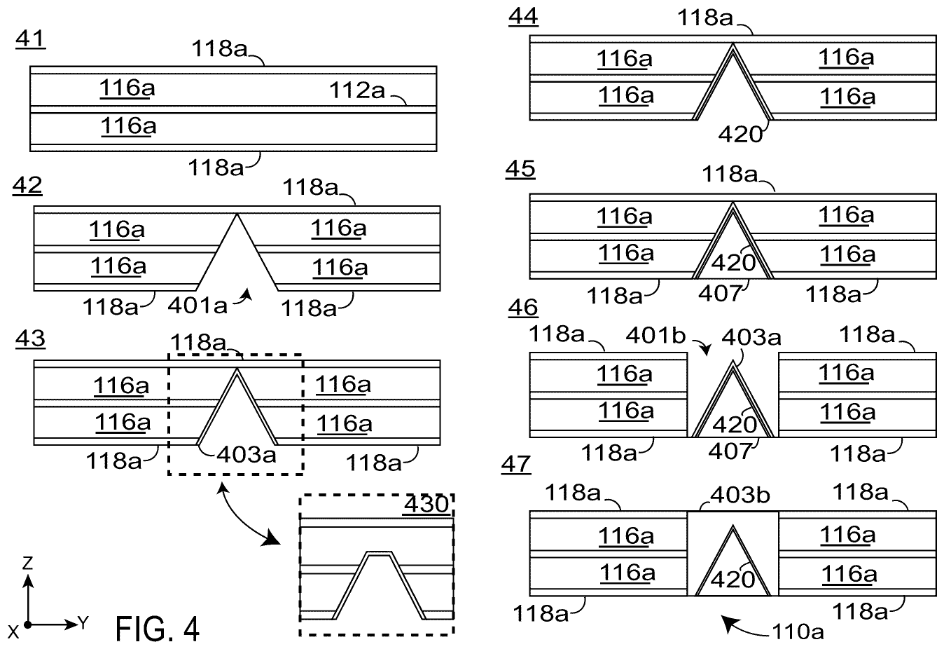

FIG. 4 schematically illustrates aspects of a method of forming a waveguide 110a (e.g., reflector waveguide, reflector block), according to some embodiments. FIG. 4 depicts a cross sectional view of a multilayer stack 106a (e.g., an edge emitting LED structure, a substrate or wafer comprising a plurality of edge emitting LEDs and waveguides). In some embodiments, the multilayer stack 106a may be at the wafer level. At block 41, the method includes providing a multilayer stack 106a. In some embodiments, the multilayer stack 106a may be provided by forming layers (e.g. epitaxially growing layers on a growth substrate) at a wafer level or providing individual wafer levels and stacking them together. In some embodiments, the growth substrate (e.g. sapphire) on which the multilayers of LED structure is grown may be the part of 106a or may be removed (e.g. by laser lift off).

At block 42, the method includes forming openings in a multilayer stack 106a. For example, the method may include etching first openings 401a in multilayer stack 106a. In some embodiments, multilayer stack 106a may be on a carrier substrate, and forming the openings 401a may comprise etching the multilayer stack 106a from a first surface to a second surface opposite the first surface of multilayer stack 106a (e.g., through multilayer stack 106a). The openings may be etched via a wet etch, a dry etch, or any suitable etching technique. The openings may be formed to provide for a particular shape or geometry of the reflector. In some embodiments, the opening may have a shape of a triangle. In some other examples, the opening may have a shape of a trapezoid, ellipsoid, hemisphere, etc.

In some embodiments, the method includes forming openings that are divots. For example, the method may include partially etching the multilayer stack 106a (e.g., openings are not formed from a first surface to a second surface opposite the first surface of the multilayer stack 106a, example shown at inset 430). The opening may be etched through an emissive layer 112a such that a reflector formed in the opening may, at least, overlap a thickness or height of the emissive layer 112a. For example, at least an emission portion (e.g., emissive layer 112a) of the multilayer stack 106a may be etched to have sloped sidewalls, and other portions (e.g., lightguide layer 116a) of the multilayer stack 106a may not be etched or fully etched (e.g., etched through the lightguide layer 116a).

At block 43, the method includes forming a dielectric layer 403a in the first opening 401a in multilayer stack 106a. The dielectric layer 403a may comprise an oxide layer, a nitride layer, a plurality of layers of oxide and/or nitride, or layer of optically tuned material.

At block 44, the method includes forming a reflective layer 420 (e.g., reflector 120) on the dielectric layer 403a in the first opening 401a. In some embodiments, a reflective layer 420 (e.g., reflector 120) is formed directly on the exposed portion of multilayer stack 106a in the first opening 401a without depositing the dielectric layer 403a in the first opening 401a. The reflective layer 420 may comprise a metal layer, a plurality of thin films, a DBR reflector coating, a dichroic, a dichroic filter, a dichroic mirror. In some embodiments, the reflective layer 420 (e.g., reflector 120) covers or overlaps a thickness of the of the emission portion.

At block 45, the method includes forming the dielectric layer 407 on the reflective layer 420 on the dielectric layer 403a in the first opening 401a. The dielectric layer 407 may be a fill layer comprising fill material. A fill material may comprise any suitable fill material such as an organic dielectric, (e.g. resin, polymer, BCB, polyimide, etc.), inorganic dielectric (e.g. silicon oxide, silicon nitride, etc.), silicate material, a transparent material, a non-transparent or opaque material fill, or any suitable material. In some embodiments, a non-transparent or opaque fill material may be used as light is not transmitted through the bottom of the waveguide (e.g., waveguide 110a).

At block 46, the method can include flipping the multilayer stack, attaching to a carrier (from the side of the dielectric layer 407 or fill layer), and removing a portion of the multilayer stack 106a around the dielectric layer 403a to form a second opening 401b. Removing a portion of the multilayer stack 106a may be done by etching. The etching may produce an angle between the angle of the edge-emitting LED opening and the angle of the reflector or reflective layer 420. The angle may be about 45 degrees or less than about 90 degrees. In some embodiments, the shape of the reflector may be a triangular prism, a pyramid, a trapezoid, or any suitable shape.

At block 47, the method includes depositing a material (e.g., dielectric, oxide, optically tuned material) to fill the removed portion of the multilayer stack 106a around the dielectric layer 403a (e.g., opening 401b at block 46). In some embodiments, optically tuned is defined as low absorption of light within the material. A low absorption may include absorbance rate of less than about 2% of a particular wavelength per unit-distance traveled. In some embodiments, a low absorption may include an absorbance rate of less than about 10%, or less than about 5%, or less than about 3%, or less than about 1% of a particular wavelength per unit-distance traveled. In some embodiments, the dielectric material can be an oxide.

In some embodiments, a waveguide 110a comprises the dielectric layer 407, reflective layer 420, dielectric layer 403a, and dielectric layer 403b. The waveguide 110a may reflect and transmit light emitted from the active layer 112a. In some embodiments, the waveguide 110a comprises an oxide material, a nitride material, a combination thereof, or any suitable dielectric material. In some embodiments, the waveguide 110a comprises multi-layer fill of suitable material.

In some embodiments, the method includes etching portions of the metallization layer 118a of the multilayer stack 106a. In some embodiments, the metallization layer 118a of the multilayer stack 106a may be formed (e.g., deposited or patterned) subsequent to block 47.

In some embodiments, a method of forming a display may comprise, subsequent to block 47, forming one or more DBI layers on surfaces of the multilayer stack 106a. For example, redistribution layers (e.g., redistribution layers 130 as shown in FIG. 1D) may be formed on top and bottom surfaces of multilayer stack 106a. A surface of the multilayer stack 106a (e.g., redistribution layers 130) may be prepared for hybrid bonding using CMP or any suitable techniques such as those described in the present disclosure (e.g., as described in the description of FIGS. 10A-10B). The method of forming the display may include bonding prepared surfaces of multilayer stacks to each other, bonding prepared surfaces of a multilayer stack and a control substrate (e.g., ROIC, substrate comprising control devices, processors, etc.) to each other, and/or bonding prepared surfaces of a multilayer stack (e.g., substrate of edge-emitting LEDs and waveguides) and a substrate comprising surface emitting LEDs and waveguides to each other.

In some embodiments, the waveguide 110a forms two separate LEDs. For example, instead of two portions of LED 119a with a waveguide 110a disposed centrally in the LED 119a as shown in FIGS. 1A-1C, a pixel may comprise one half of the LED 119a and one half of the waveguide 110a. A first pixel may comprise a left portion of the LED 119a and a left portion of the waveguide 110a, and second pixel may comprise a right portion of LED 119a and a right portion of waveguide 110a. (e.g., pixel 123 of FIGS. 1A-1C may be split in half to form two pixels).

In some embodiments, the multilayer stack 106a may be etched or partially etched to form a larger separation between the pixels. For example, a spacing between adjacent LEDs 119a may be increased to have a larger separation between the pixel (e.g. for dicing). In some embodiments, the multilayer stack 106a may be diced to separate one or more LEDs and corresponding waveguides from other LEDs and corresponding waveguides (e.g., for singulation or for a suitable size or arrangement of pixels in an XY grid, etc.).

FIG. 5 schematically illustrates aspects of DTIs, according to some embodiments. In example configurations 501, 502, and 503, three LEDs 119a1, 119a2, and 119a3 (or pixels of display) defined by DTIs 125a, 125b, and 125c. The DTIs 125a, 125b, and 125c may comprise a reflector. In example configuration 501, the DTI 125a may comprise a material (e.g., fill material) comprising a metal, polysilicon (polySi), semiconductor coatings, reflector coating, DBR coatings, or some combination thereof. In example configuration 502, DTI 125b may comprise an outer portion 525b1 and an inner portion 525b2. The outer portion 525b1 may comprise a material comprising a metal, polysilicon (polySi), semiconductor coatings, reflector coating, or some combination thereof. The inner portion 525b2 may comprise a dielectric material (e.g. an oxide). In some embodiments, the outer portion of DTI (e.g., outer portion 525b1 of DTI 125b, or outer portion 525cl of DTI 125c) may be a reflector (e.g., at a sidewall of an edge-emitting LED) that reflects light from an edge-emitting LED 119a2 internally (e.g., internal to the edge-emitting LED 119a2) towards a reflector in a waveguide (e.g., waveguide 110a) to direct or reflect light towards a viewing surface of the display to exit the display. In some embodiments, the outer portion of the DTI (e.g., outer portion 525b1 of DTI 125b, or outer portion 525cl of DTI 125c, or the portion shown directly adjacent to or facing LED 119a2) is reflecting light internally for LED 119a2 as well as LED 119al (e.g., outer portion 525b1 of DTI 125b, or outer portion 525cl of DTI 125c, or the portion shown directly adjacent to or facing LED 119a1). In example configuration 503, the DTI 125c is similar to DTI 125b except an outer portion 525cl is on a bottom outer portion of the DTI 125c. For example, outer portion 525cl corresponds to outer portion 525b2, and inner portion 525c2 corresponds to inner portion 525b1. An inset shows a variation of DTI 125c with a different shape. For example, an opening in a multilayer stack may be etched in a particular shape for the DTI. In some embodiments, the multilayer stack may be etched to form a particular shape of the DTI 125c.

In some embodiments, the DTIs 125a, 125b, and 125c are spaced apart by a distance corresponding to a single pixel pitch. In some embodiments, the distance may correspond to any suitable number of pixel pitch (e.g., one, two, three or more times the pixel pitch).

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 608a and/or 608b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. patent application Ser. No. 18/391,173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 6A and 6B schematically illustrate cross-sectional side views of first and second elements 602, 604 prior to and after, respectively, a process for forming a directly bonded structure, and more particularly a hybrid bonded structure, according to some embodiments. In FIG. 6B, a bonded structure 600 comprises the first and second elements 602 and 604 that are directly bonded to one another at a bond interface 618 without an intervening adhesive. Conductive features 606a of a first element 602 may be electrically connected to corresponding conductive features 606b of a second element 604. In the illustrated hybrid bonded structure 600, the conductive features 606a are directly bonded to the corresponding conductive features 606b without intervening solder or conductive adhesive.

The conductive features 606a and 606b of the illustrated embodiment are embedded in, and can be considered part of, a first bonding layer 608a of the first element 602 and a second bonding layer 608b of the second element 604, respectively. Field regions of the bonding layers 608a, 608b extend between and partially or fully surround the conductive features 606a, 606b. The bonding layers 608a, 608b can comprise layers of non-conductive materials suitable for direct bonding, as described above, and the field regions are directly bonded to one another without an adhesive. The non-conductive bonding layers 608a, 608b can be disposed on respective front sides 614a, 614b of base substrate portions 610a, 610b.

The first and second elements 602, 604 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 602, 604, and back-end-of-line (BEOL) interconnect layers over such semiconductor portions. The bonding layers 608a, 608b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 610a, 610b, and can electrically communicate with at least some of the conductive features 606a, 606b. Active devices and/or circuitry can be disposed at or near the front sides 614a, 614b of the base substrate portions 610a, 610b, and/or at or near opposite backsides 616a, 616b of the base substrate portions 610a, 610b. In other embodiments, the base substrate portions 610a, 610b may not include active circuitry, but may instead comprise dummy substrates, passive interposers, passive optical elements (e.g., glass substrates, gratings, lenses), etc. The bonding layers 608a, 608b are shown as being provided on the front sides of the elements, but similar bonding layers can be additionally or alternatively provided on the back sides of the elements.

In some embodiments, the base substrate portions 610a, 610b can have significantly different coefficients of thermal expansion (CTEs), and bonding elements that include such different based substrate portions can form a heterogenous bonded structure. The CTE difference between the base substrate portions 610a and 610b, and particularly between bulk semiconductor (typically single crystal) portions of the base substrate portions 610a, 610b, can be greater than 5 ppm/° C. or greater than 10 ppm/° C. For example, the CTE difference between the base substrate portions 610a and 610b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 610a, 610b can comprise optoelectronic single crystal materials, including perovskite materials, that are useful for optical piezoelectric or pyroelectric applications, and the other of the base substrate portions 610a, 610b comprises a more conventional substrate material. For example, one of the base substrate portions 610a, 610b comprises lithium tantalate (LiTaO₃) or lithium niobate (LiNbO₃), and the other one of the base substrate portions 610a, 610b comprises silicon (Si), quartz, fused silica glass, sapphire, or a glass. In other embodiments, one of the base substrate portions 610a, 610b comprises a III-V single semiconductor material, such as gallium arsenide (GaAs) or gallium nitride (GaN), and the other one of the base substrate portions 610a, 610b can comprise a non-III-V semiconductor material, such as silicon (Si), or can comprise other materials with similar CTE, such as quartz, fused silica glass, sapphire, or a glass. In still other embodiments, one of the base substrate portions 610a, 610b comprises a semiconductor material and the other of the base substrate portions 610a, 610b comprises a packaging material, such as a glass, organic or ceramic substrate.

In some arrangements, the first element 602 can comprise a singulated element, such as a singulated integrated device die. In other arrangements, the first element 602 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 604 can comprise a singulated element, such as a singulated integrated device die. In other arrangements, the second element 604 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 602, 604 are shown, any suitable number of elements can be stacked in the bonded structure 600. For example, a third element (not shown) can be stacked on the second element 604, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 602. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 608a, 608b, the bonding layers 608a, 608b can be prepared for direct bonding. Non-conductive bonding surfaces 612a, 612b at the upper or exterior surfaces of the bonding layers 608a, 608b can be prepared for direct bonding by polishing, for example, by chemical mechanical polishing (CMP). The roughness of the polished bonding surfaces 612a, 612b can be less than 30 Å rms. For example, the roughness of the bonding surfaces 612a and 612b can be in a range of about 0.1 Å rms to 15 Å rms, 0.5 Å rms to 10 Å rms, or 1 Å rms to 5 Å rms. Polishing can also be tuned to leave the conductive features 606a, 606b recessed relative to the field regions of the bonding layers 608a, 608b.

Preparation for direct bonding can also include cleaning and exposing one or both of the bonding surfaces 612a, 612b to a plasma and/or etchants to activate at least one of the surfaces 612a, 612b. In some embodiments, one or both of the surfaces 612a, 612b can be terminated with a species after activation or during activation (e.g., during the plasma and/or etch processes). Without being limited by theory, in some embodiments, the activation process can be performed to break chemical bonds at the bonding surface(s) 612a, 612b, and the termination process can provide additional chemical species at the bonding surface(s) 612a, 612b that alters the chemical bond and/or improves the bonding energy during direct bonding. In some embodiments, the activation and termination are provided in the same step, e.g., a plasma to activate and terminate the surface(s) 612a, 612b. In other embodiments, one or both of the bonding surfaces 612a, 612b can be terminated in a separate treatment to provide the additional species for direct bonding. In various embodiments, the terminating species can comprise nitrogen. For example, in some embodiments, the bonding surface(s) 612a, 612b can be exposed to a nitrogen-containing plasma. Other terminating species can be suitable for improving bonding energy, depending upon the materials of the bonding surfaces 612a, 612b. Further, in some embodiments, the bonding surface(s) 612a, 612b can be exposed to fluorine. For example, there may be one or multiple fluorine concentration peaks at or near a bond interface 618 between the first and second elements 602, 604. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 600, the bond interface 618 between two non-conductive materials (e.g., the bonding layers 608a, 608b) can comprise a very smooth interface with higher nitrogen (or other terminating species) content and/or fluorine concentration peaks at the bond interface 618. In some embodiments, the nitrogen and/or fluorine concentration peaks may be detected using various types of inspection techniques, such as SIMS techniques. The polished bonding surfaces 612a and 612b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 608a and 608b can be directly bonded to one another without an adhesive. In some embodiments, the elements 602, 604 are brought together at room temperature, without the need for application of a voltage, and without the need for application of external pressure or force beyond that used to initiate contact between the two elements 602, 604. Contact alone can cause direct bonding between the non-conductive surfaces of the bonding layers 608a, 608b (e.g., covalent dielectric bonding). Subsequent annealing of the bonded structure 600 can cause the conductive features 606a, 606b to directly bond.

In some embodiments, prior to direct bonding, the conductive features 606a, 606b are recessed relative to the surrounding field regions, such that a total gap between opposing contacts after dielectric bonding and prior to anneal is less than 15 nm, or less than 10 nm. Because the recess depths for the conductive features 606a and 606b can vary across each element, due to process variation, the noted gap can represent a maximum or an average gap between corresponding conductive features 606a, 606b of two joined elements (prior to anneal). Upon annealing, the conductive features 606a and 606b can expand and contact one another to form a metal-to-metal direct bond.

During annealing, the conductive features 606a, 606b (e.g., metallic material) can expand while the direct bonds between surrounding non-conductive materials of the bonding layers 608a, 608b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 606a, 606b can comprise discrete pads, contacts, electrodes, or traces at least partially embedded in the non-conductive field regions of the bonding layers 608a, 608b. In some embodiments, the conductive features 606a, 606b can comprise exposed contact surfaces of TSVs (e.g., through silicon vias).

As noted above, in some embodiments, in the elements 602, 604 of FIG. 6A prior to direct bonding, portions of the respective conductive features 606a and 606b can be recessed below the non-conductive bonding surfaces 612a and 612b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 606a, 606b or to average depths of the recesses relative to local non-conductive field regions. Even for an individual conductive feature 606a, 606b, the vertical recess can vary across the feature, and so can be measured at or near the lateral middle or center of the cavity in which a given conductive feature 606a, 606b is formed, or can be measured at the sides of the cavity.

Beneficially, the use of hybrid bonding techniques (such as Direct Bond Interconnect, or DBIR, techniques commercially available from Adeia of San Jose, CA) can enable high density of connections between conductive features 606a, 606b across the direct bond interface 618 (e.g., small or fine pitches for regular arrays).

In some embodiments, a pitch p of the conductive features 606a, 606b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 606a and 606b to one of the lateral dimensions (e.g., a diameter) of the bonding pad is less than is less than 20, or less than 10, or less than 5, or less than 3 and sometimes desirably less than 2. In various embodiments, the conductive features 606a and 606b and/or traces can comprise copper or copper alloys, although other metals may be suitable, such as nickel, aluminum, or alloys thereof. The conductive features disclosed herein, such as the conductive features 606a and 606b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 602, 604, as shown, the orientations of one or more conductive features 606a, 606b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 606b in the bonding layer 608b (and/or at least one internal conductive feature, such as a BEOL feature) of the upper element 604 may be tapered or narrowed upwardly, away from the bonding surface 612b. By way of contrast, at least one conductive feature 606a in the bonding layer 608a (and/or at least one internal conductive feature, such as a BEOL feature) of the lower element 602 may be tapered or narrowed downwardly, away from the bonding surface 612a. Similarly, any bonding layers (not shown) on the backsides 616a, 616b of the elements 602, 604 may taper or narrow away from the backsides, with an opposite taper orientation relative to front side conductive features 606a, 606b of the same element.

As described above, in an anneal phase of hybrid bonding, the conductive features 606a, 606b can expand and contact one another to form a metal-to-metal direct bond. In some embodiments, the materials of the conductive features 606a, 606b of opposite elements 602, 604 can interdiffuse during the annealing process. In some embodiments, metal grains grow into each other across the bond interface 618. In some embodiments, the metal is or includes copper, which can have grains oriented along the 1011 crystal plane for improved copper diffusion across the bond interface 618. In some embodiments, the conductive features 606a and 606b may include nanotwinned copper grain structure, which can aid in merging the conductive features during anneal. There is substantially no gap between the non-conductive bonding layers 608a and 608b at or near the bonded conductive features 606a and 606b. In some embodiments, a barrier layer may be provided under and/or laterally surrounding the conductive features 606a and 606b (e.g., which may include copper). In other embodiments, however, there may be no barrier layer under the conductive features 606a and 606b.

Embodiments herein may provide for improved (e.g., more efficient or high-volume) manufacturing of displays (e.g., display devices, LED displays, LED display devices, micro-LED displays, micro-LED display devices) using stacked and bonded monochromatic wafers, substrates, or dies. Embodiments herein may provide for a display comprising at least one stackable layer of edge-emitting LEDs and methods for forming the same. The display may further comprise one or more layers of edge-emitting LEDs and/or one or more layers of surface-emitting LEDs that are attached to (e.g., directly bonded, hybrid bonded) the at least one layer of edge-emitting LEDs. A display device comprising at least one stackable layer of edge-emitting LEDs and corresponding waveguides may enable increased surface area of an active layer per pixel, allowing for greater light output and increase in luminance over conventional displays.

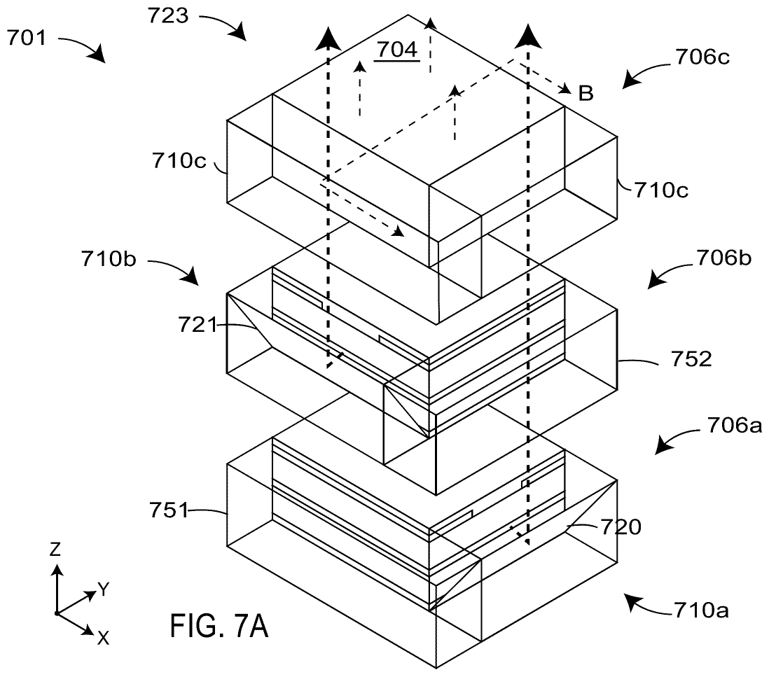

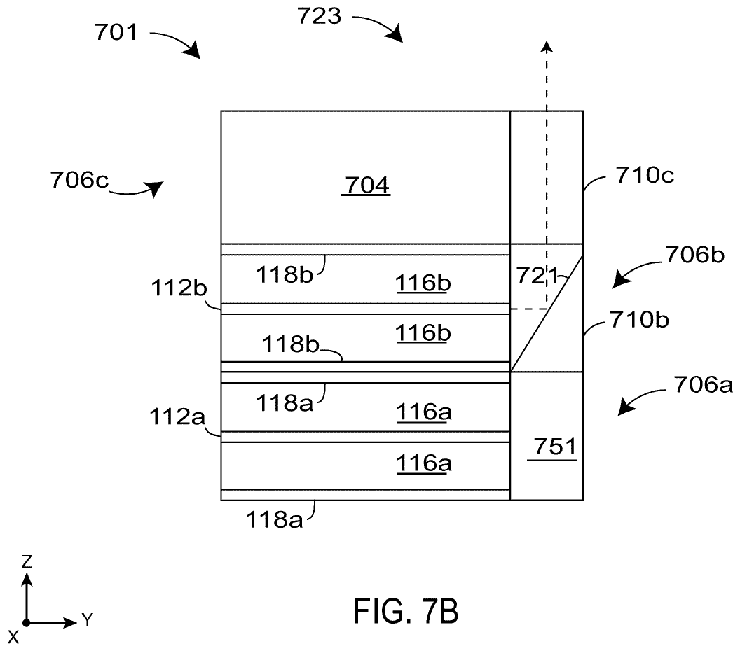

FIGS. 7A-7B schematically illustrates example views of a pixel configuration in a display device, according to some embodiments. FIG. 7A shows an example isometric view of a pixel configuration in a display device 701. FIG. 7B shows an example cross section view of a pixel configuration in a display device 701 at dotted lines B in FIG. 7A.

The display device 701 comprises a substrate 706c (e.g., layer, panel, wafer, die, etc.) disposed on two multilayer stacks (e.g., multilayer stack 706a and multilayer stack 706b). In some embodiments, the multilayer stacks 706a and 706b may correspond to (e.g., may be similar to or the same as) multilayer stacks 106a and 106b, respectively, except that a respective opening and waveguides 710a and 710b in the multilayer stacks 706a and 706b are disposed on one side of a pixel 723 instead of being centrally disposed (e.g., as in the pixel 123a). The orientation of the multilayer stacks 706a and 706b are orthogonal to one another (e.g., waveguides 710a and 710b are orthogonal to each other and not overlapping). In some embodiments, waveguides 710a and 710b are parallel, but on the opposite sides of the multilayer stacks 706a and 706b. The reflector 720 and reflector 721 may correspond to (e.g., be the same as or similar to) reflector 120 and reflector 121, respectively.

The substrate 706c may comprise a plurality of surface emitting LEDs and light guides or waveguides (shown in FIG. 7A as LED 704 and waveguides 710c). The surface emitting LEDs may comprise a phosphor. The substrate 706c may comprise waveguides 710c (e.g., waveguide block comprising fill material like oxide or glass) disposed in openings of the substrate 706c. The waveguides 710c may be superimposed over top the waveguides 710a and 710b of the multilayer stacks 706a and 706b. The waveguides 710c may comprise optically tuned material that allows for the transmission of light emitted from the first multilayer stack 706a and second multilayer stack 706b. In some embodiments, the waveguides 710a and 710b comprises a dielectric, an oxide, or a combination thereof optically tuned to allow for the transmission of light emitted by the active layer of the first multilayer stack 706a and the transmission of light emitted by the active layer of the second multilayer stack 706b.

It may be appreciated that the first and second multilayer stacks 706a and 706b are not optically superimposed (e.g., comprising light paths that overlap each other) as the first and second multilayer stacks 106a and 106b of FIG. 1B. When multilayer stacks are not optically superimposed, the corresponding waveguides of the multilayer stacks may comprise mirrors such as full reflective mirrors or mirrors tuned to reflect a wavelength range instead of dichroic mirrors, dichroic filters, or dichroic reflectors. For example, light emitted from the active layer of the first multilayer stack 706a and second multilayer stack 706b may exit to respective waveguides 710a and 710b that are positioned orthogonal to one another with non-overlapping light paths, and reflector 720 and reflector 721 may each be a metalized reflector.

In some embodiments, the second multilayer stack 706b comprises a dielectric block 752 that allows for the transmission of light emitted from the first multilayer stack 706a. The first multilayer stack 706a may comprise a block 751. In some embodiments, the block 751 may be a semiconductor material or fill material supporting the area underneath the waveguide 710b of the second multilayer stack 706b. In some embodiments, a side or edge of the LED in of the first multilayer stack 706a (e.g., any suitable side, edge, or portion of a side or edge of the LED that is not at an exit opening or corresponding waveguide) may comprise mirror coatings to reflect light towards the exit opening or waveguides. For example, a side of the first multilayer stack 706a adjacent to block 751 may comprise a mirror coating. In some embodiments, block 751 may be similar to an inner portion 525b2 of DTI 125b, and a metal layer, distributed Bragg reflective (DBR) coatings or other type of reflective surface (e.g., outer portion 525b1 of DTI 125b in FIG. 5) is adjacent to an edge of an LED. In some embodiments, the block 751 may be a portion of the multilayer stack 706a, increasing the surface area of the active layer to increase light output emitted by the active layer of the first multilayer stack 706a.

In some embodiments, the substrate 706c is attached (e.g., directly bonded, hybrid bonded) to the multilayer stack 706b, and the multilayer stack 706b is attached (e.g., directly bonded, hybrid bonded) to the multilayer stack 706a. The waveguide 710c may be directly bonded or hybrid bonded to the waveguide 710b and/or dielectric block 752. The waveguide 710b may be directly bonded or hybrid bonded to the block 751. The dielectric block 752 may be directly bonded or hybrid bonded to the waveguide 710a. In some other embodiments, the multilayer stacks 706a, 706b, and substrate 706c are stacked or joined together by adhesives (e.g. epoxy, flip chip connections, etc.). In some other embodiments, the multilayer stacks 706a-c are stacked or joined together by metal to metal bonding (e.g. thermo-compression bonding).

In some embodiments, a substrate comprising a surface-emitting LED with an active layer and transport layers and/or light guides layers may replace a third multilayer stack 106c of a display device (e.g., display 101).

FIGS. 8A-8B schematically illustrate example top views of a display device, according to some embodiments. For example, FIGS. 8A-8B may illustrate variations of a pixel configuration of a display 101 of FIG. 1C. The display devices may have similar features to the display 101 described above, and therefore the description of similar features is omitted for brevity. In some embodiments, the pixels 823a-e (e.g., pixel 823a, pixel 823b, pixel 823c, pixel 823d, pixel 823e), multilayer stack 806, waveguides 810, and metallization layer 818 correspond to pixel 123, multilayer stack 106c, waveguides 110c, and metallization layers 118c of display 101.

FIG. 8A shows the pixels 823a are separated by a DTI 125 (e.g., shown as a single pixel with surrounding DTI) and comprise openings on all 4 sides of the square shaped pixel 823a. Disposed in the openings are waveguides 810 similar to that described in FIG. 1D, the difference being that the openings and waveguides 810 are disposed on the exterior of the edge-emitting LED, and therefore comprise 4 emissive faces (or sides) instead of a singular central face (e.g., four emissive portions on each edge of the pixel 823a instead of a central emissive portion of pixel 123a). Although one waveguide surface (e.g., waveguide 810 corresponding to waveguide 810) is shown it is appreciated that the waveguide of the second layer (e.g. waveguide corresponding to waveguide 110b of multilayer stack 106b) and waveguide of the first layer (e.g., waveguide corresponding to waveguide 110a of multilayer stack 106a) are superimposed over one another as in the illustrative example of FIG. 1D. In some embodiments, each pixel 823a or any suitable pixel, such as those mentioned in embodiments of this disclosure has a separate intra-pixel separation. In some embodiments, each pixel 823a or any suitable pixel, such as those mentioned in embodiments of this disclosure has a separate optical element (e.g., lens) disposed over the pixel for light manipulation (e.g., collimation). In some embodiments the optical element is a square lens 870, or a diffuser. In some other embodiments the optical element is an optical filter or a quantum dot layer.

In some embodiments, a substrate with surface-emitting LEDs may be used in place of a multilayer stack comprising edge-emitting LEDs and waveguides 810c. For example, a surface-emitting LED 704 may be in place of the metallization layer 818 in FIG. 8A. At the top right of FIG. 8A, a top down view of pixel 823a may show details of different layers superimposed on each other or details of underlying layers of the multilayer stacks (e.g., corresponding to multilayer stack 106a or 106b). In some embodiments, block 853 may correspond to a surface-emitting LED 704. In some embodiments, a bottom multilayer stack corresponding to multilayer stack 106a may have reflectors at block 851 and waveguides at block 852. In some embodiments, an intermediate multilayer stack corresponding to multilayer stack 106b may have reflectors at block 852 and waveguides at block 851. The reflectors (e.g., mirror on sides of edge-emitted LED) may confine emitted light to an LED of a multilayer stack and the waveguides (e.g., reflector block with angled mirror) may enable emitted light of the LED to exit the LED or multilayer stack.

FIG. 8B shows other example variations of pixel configurations. In the example of pixel 823b, the waveguide 810 is on one side of the pixel structure instead of being centrally located (e.g., pixel 123a of FIG. 1D). For example, a pixel configuration may comprise a portion of the pixel 123a of FIG. 1E (e.g., edge emitting LED 119a-c and adjacent waveguide 110a-c). In the example of pixel 823c, the waveguide 810 forms a cross shape on the pixel structure. In the example of pixel 823d, the waveguide 810 forms a small square centrally in the pixel structure, a line in the square indicating the reflector. In some embodiments, each of the multilayer stack has a small waveguide 810, which is offset from the similar waveguide within multilayer stack above or below it. In some embodiments, the waveguide 810 may be circular, rectangular, elliptical or any other regular or irregular shapes. In the example of pixel 823e, the waveguide 810 forms an “X” shape centrally in the pixel structure where one part of a line of the “X” is in a different layer than the other. In some embodiments, the waveguides 810 are formed in a same layer. In some embodiments, the waveguide 810 and corresponding reflector may be any suitable shape or suitable size. In some embodiments, a substrate with surface-emitting LEDs may be used in place of a multilayer stack comprising edge-emitting LEDs and waveguides 810 of pixels 823b-e.

FIG. 8B schematically illustrate example top views of a pixel 823f, pixel 823g, pixel 823h, and pixel 823i. FIG. 8B may illustrate variations of a pixel configuration of a display in which a substrate of surface-emitting LEDs (e.g., LED 119d, 704) is on top of multilayer stacks 106a and 106b. In some embodiments, pixels 823f-i, LED 804, and waveguide 810 of display devices in FIG. 8B correspond to pixel 123a with a LED 119d (e.g., surface emitting LED) and waveguide 110d in place of the top layer (e.g., substrate, multilayer stack 106c) of the display device. In some embodiments, the LED 804 is capable of emitting light different to that of the active layers therebelow. In some embodiments, LED 804 may be capable of emitting light similar to that of the active layers therebelow.

A top view of pixel 823f shows a general pixel configuration. A top view of pixel 823g shows example detail of a pixel 823f. For example block 853 may correspond to a waveguide in an intermediate multilayer stack corresponding to waveguide 110b and multilayer stack 106b, and block 854 may correspond to a waveguide in a bottom multilayer stack corresponding to waveguide 110a and multilayer stack 106a.

A top view of pixel 823h shows a pixel configuration. For example, block 825 may correspond to a waveguide in an intermediate multilayer stack corresponding to waveguide 110b and multilayer stack 106b, and block 826 may correspond to a waveguide in a bottom multilayer stack corresponding to waveguide 110a and multilayer stack 106a.

A top view of pixel 823i shows example detail of a variation to example pixel 823h. For example, the top view of pixel 823i may details of different layers superimposed on each other. In some embodiments, a multilayer stack with edge-emitting LEDs and waveguides may be used in place of a substrate comprising surface-emitting LEDs 804. For example, block 832 may correspond to a waveguide in a top multilayer stack corresponding to waveguide 110c and multilayer stack 106c. Block 833 may correspond to a waveguide in an intermediate multilayer stack corresponding to waveguide 110b and multilayer stack 106b, and block 834 may correspond to a waveguide in a bottom multilayer stack corresponding to waveguide 110a and multilayer stack 106a.

In some embodiments, an example display device is similar to or the same as display device 701 of FIG. 7A-7B except a substrate (e.g., comprising surface emitting LEDs) is used in place of multilayer stack 706a of display device 701. The bottom substrate may comprise a plurality of surface emitting LEDs. In some embodiments, a surface emitting LED may comprise a phosphor layer.

In some embodiments, a reflector or mirror may be a dichroic mirror or dichroic filter. For example, a reflector may transmit light of wavelengths in a first range of wavelengths and reflect light of wavelengths in another range of wavelengths (e.g., red, green, blue, red/green, green/blue, red/blue light). In some embodiments, the reflector or mirror may be a complete mirror or a full mirror.

In some embodiments, the display device may further comprise a brightness enhancement film (BEF). The BEF may manage angular light output from the display device. The BEF may use a prismatic structure to focus light towards on-axis viewers of the display. The BEF may refracts light within the viewing cone (up to 35° off the perpendicular) toward the viewer. Light outside this angle is reflected back and recycled until it exits at the proper angle. The BEF may minimize or reduce coupling to adjacent surfaces. The BEF can be used alone or two BEFs can be crossed, e.g., at 90 degrees to each other. A single sheet or BEF may provide up to 60% increase in brightness and two sheets crossed at 90° can provide up to 120% brightness increase.

In some embodiments, a display device may comprise monochromatic stacks of wafers using edge-emitted LEDs with reflectors from a same edge (e.g., of the pixel). In some embodiments, each multilayer stack 106a-c is an LED wafer of one particular color. For example, a wafer of red edge-emitting LEDs (e.g., multilayer stack 106c) may be stacked on or attached to a wafer of green edge-emitting LEDs (e.g., multilayer stack 106b), and a wafer of green edge-emitting LEDs may be stacked on or attached to a wafer of blue edge-emitting LEDs (e.g., multilayer stack 106a). Each wafer may comprise reflecting blocks or cubes (e.g., waveguides 110a, 110b, 110c) with appropriate dichroic coatings next to the emission layers of the red edge-emitting LEDs, green edge-emitting LEDs, and blue edge-emitting LEDs. The reflecting block or cube (e.g., waveguide 110c) next to red edge-emitting LED may comprise a dichroic film (e.g., reflector 122) tuned to reflect red light and transmit green and blue light. The reflecting block or cube (e.g., waveguide 110b) next to green edge-emitting LED may comprise a dichroic film (e.g., reflector 121). The dichroic film (e.g., reflector 121) next to the green edge-emitting LED may comprise a dichroic film tuned to reflect green light and transmit blue light. In some embodiments, the reflecting block or cube (e.g., waveguide 110a) next to the blue edge-emitting LED may not comprise a dichroic film and may be a full mirror (e.g., reflector 120).

In some embodiments, a display device (e.g., display device of FIGS. 7A-7B) may comprise a wafer with a surface emitting LED (e.g., red LED), and wafers with edge-emitting LEDs (e.g., green and blue edge-emitting LEDs). For example, a top substrate (e.g., substrate 706c) may comprise surface-emitting red LEDs, and intermediate substrate (e.g., multilayer stack 706b) may comprise a wafer of green edge-emitting LEDs, and a bottom substrate (e.g., multilayer stack 706a) may comprise a wafer of blue edge-emitting LEDs. Reflector blocks or cubes may be next to emission layers of edge-emitting LEDs. For example, there may be no reflector block or cube next to the red surface-emitting LED. A reflector block or cube (e.g., waveguide 710b) next to a green edge-emitting LED may comprise a dichroic film (e.g., reflector 721) tuned to reflect green light and transmit blue light. A reflector block or cube (e.g., 710a) next to a blue edge-emitting LED may not comprise a dichroic film and may comprise a full mirror (e.g., reflector 720). In some embodiments, the reflector blocks may be from a same edge (e.g., of the pixel). In some embodiments, the reflector blocks may be from perpendicular edges (e.g., of the pixel). For example, a reflector block next to green edge-emitting LED may be from a first edge of a pixel, and a reflector block next to a blue edge-emitting LED may be from a second edge of the pixel, the second edge may be perpendicular to the first edge of the pixel.

In some embodiments, a mirror may be a full mirror, a dichroic mirror, or a dichroic filter. In some embodiments, where light emission of LEDs overlaps in a vertical dimension, a dichroic mirror or a dichroic filter may be used. In some embodiments, where there is no overlap of different colored lights, a full mirror may be used.

In some embodiments, reflectors may be near intra-pixel separation portion of a substrate comprising edge-emitting LEDs. For example, a reflector block with reflectors at different angles may separate a first LED and a second LED of a substrate comprising edge-emitting LEDs. In some embodiments, a reflective layer comprising the reflector may be formed to cover only at least an emission portion with sloped sidewalls (e.g., from a bottom portion of the edge-emitting LED to an emission portion of the edge-emitting LED and not a top portion of the edge-emitting LED). In some embodiments, there may be a larger separation for dicing. For example, a top portion of two reflectors corresponding to adjacent edge-emitting LEDs may not meet to form a point in the substrate (e.g., triangular shape), and may have a flat top (e.g., form a trapezoidal shape).

In some embodiments, a lens may be on each pixel. Each pixel may comprise light emitted from edges of each edge-emitting LED in a top view. A square shaped or circular shaped lens may be on each pixel. In some embodiments, lens on each pixel may be a Fresnel lens. In some embodiments, a display device may comprise three substrates comprising edge-emitting LEDs of three colors. All three colors of edge-emitting LEDs may be superimposed from a top view, and all three colors may overlap. Each pixel may have a separate intra-pixel separation. Each pixel may have a separate lens for light collimation.

In some embodiments, a display device may comprise reflectors in a central or center portion of an edge-emitting LED (e.g., corresponding to one pixel of a display device). The reflectors may be positioned in a center portion of a pixel, and distribute light emitted from edge-emitting LEDs surrounding the reflectors (e.g., right and left to the reflectors) to a center portion of the pixel.

In some embodiments, each pixel may have a separate intra-pixel separation. In some embodiments, intra-pixel separation may be coated with a reflective coating to reflect light inwards towards an extraction area (e.g., of a pixel). Each pixel may have a separate lens for light collimation. A reflective coating on sidewalls may be used for intra-pixel separation.

In some embodiments, reflectors at an edge of an LED may be used for central edge emission (e.g., extraction of emitted light from an edge-emitting LED in a central portion of a pixel). Reflectors (e.g., comprising metal, polySi, reflector coatings, etc.) may be at one end of the LED wave guide. In some embodiments, reflectors may be at opposite edges of a pixel area. An oxide or a dielectric material may be in an interior portion of the reflector.

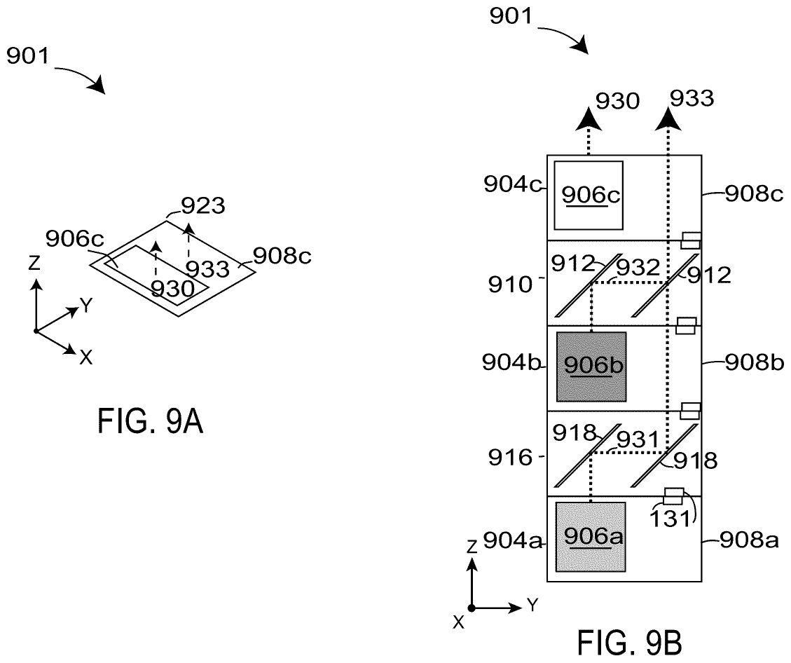

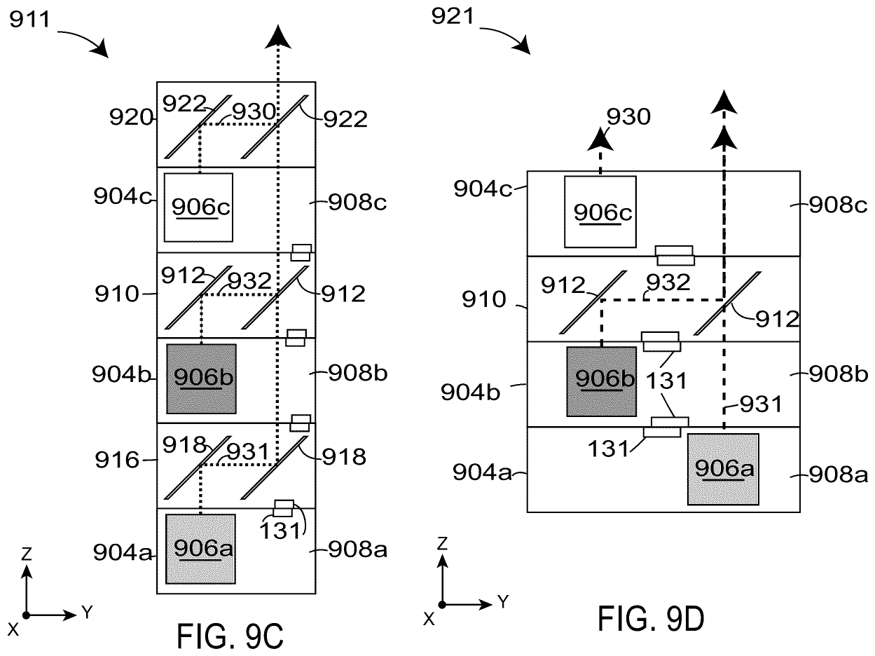

FIGS. 9A-9B schematically illustrates a display 901 (e.g., display device, LED display or display device, micro-LED display or display device), according to some embodiments. FIG. 9A shows a perspective view of a pixel 923, and FIG. 9B shows a side view of pixel 923. In FIG. 9B a pixel 923 comprises three sub-pixels or LEDs (e.g., LED 906a, LED 906b, LED 906c). Each sub-pixel or LED may emit a distinct color of light. For example, LEDs 906a, 906b, and 906c may comprise red (R), green (G), and blue (B) LEDs respectively. In another example, LEDs 906a, 906b, and 906c may comprise B, G, and R LEDs respectively. The singulated LEDs 906c disposed in a top substrate 904c may be red LEDs emitting red light. In some embodiments, the red LEDs may comprise a material that emits red light (e.g., aluminum gallium indium phosphide (AlGaInP), aluminum gallium arsenide (AlGaAs), or any suitable material used to generate red light). In some embodiments, the green LEDs may comprise a material that emits green light (e.g., indium gallium nitride (InGaN), gallium phosphide (GaP), or any suitable material used generate green light). In some embodiments, the blue LEDs may comprise a material that emits blue light (e.g., indium gallium nitride (InGaN) or any suitable material used to generate blue light). In some embodiments, a phosphor layer may be used for color conversion in an LED substrate (e.g., AlGaInP). In some embodiments, the singulated LEDs 906c may be green or blue LEDs with a quantum dot layer or phosphor to down convert the green or blue emitted light to red light. The singulated LEDs 906b disposed in the intermediate substrate 904b may be green LEDs and emit green light. The singulated LEDs 906a disposed in the bottom substrate 904a may be blue LEDs and emit blue light.

The display 901 comprises a plurality of substrates (e.g., a bottom substrate 904a, an intermediate substrate 904b, and a top substrate 904c). Each substrate 904a-c comprises a plurality of LEDs 906a-c (e.g., singulated LEDs) embedded or disposed in a respective dielectric layer 908a-c. The substrates (e.g., substrates 904a-c or any suitable substrate or layer as mentioned in the present disclosure) may comprise any suitable substrate such as those mentioned in the present disclosure. For example the substrates may comprise dummy substrates, passive interposers, passive optical elements (e.g., glass substrates, gratings, lenses), or materials used for base substrate portions 610a, 610b as described in reference to FIGS. 6A-6B.

In some embodiments, the dielectric layer 908a-c may comprise a transparent oxide. In some embodiments, the respective dielectric layer 908a-c may comprise an oxide material (e.g., silicon oxide), a nitride material, a combination thereof, or any suitable dielectric material. In some embodiments, the dielectric layer 908a-c may comprise an optically tuned dielectric that reduces the absorption of the light transmitted by the LEDs 906a-c. The dielectric layers (e.g., dielectric layers 908a-c, or any suitable layer such as those mentioned in embodiments of the present disclosure) each comprise a dielectric material. The dielectric layers may comprise a same material or different materials. The dielectric material may be any suitable dielectric material such as dielectric materials mentioned in the present disclosure. For example dielectric material may comprise oxides, nitrides, oxynitrides, carbonitrides, and oxycarbonitrides, silicon oxide, silicon nitride, silicon oxynitride, silicon carbonitride, silicon oxycarbonitride, non-conductive material such as a dielectric material or an undoped semiconductor material, such as undoped silicon, which may include native oxide, silicon oxide, silicon nitride, silicon carbide, low K dielectric materials, SiCOH dielectrics, diamond-like carbon or a material comprising a diamond surface. For example the dielectric layers may comprise materials used for bonding layer 608a and 608b of FIG. 6B.

The display 901 further comprises a plurality of waveguide layers (e.g., first layer 910, and second layer 916). The first layer 910 may disposed on the intermediate substrate 904b and between the top substrate 904c and the intermediate substrate 904b. The second layer 916 may be disposed on the bottom substrate 904a, and between the intermediate substrate 904b and the bottom substrate 904a. Each waveguide layer (e.g., first layer 910 and second layer 916) may comprise optical components such as mirrors (e.g., first mirrors 912 and second mirrors 918). LEDs 906b and LEDs 906a may emit light 932 and light 931 that is guided by the mirrors 912 and 918 respectively to exit a display surface of the display 901 (e.g., light 933).

Each of the plurality of substrates 904a-c may be directly bonded to a vertically adjacent substrate without the use of an intervening adhesive. In some embodiments, the waveguide layers (e.g., first layer 910 and second layer 916) may be formed on a corresponding substrate (e.g., intermediate substrate 904b and bottom substrate 904a, respectively). In some embodiments the layers and/or substrates may be directly bonded (e.g., hybrid bonded) to a vertically adjacent layer and/or substrate without the use of an intervening adhesive. Additional detail regarding hybrid bonds and hybrid bonding of substrates may be found in the present disclosure, e.g., at least at the description of FIGS. 6A and 6B.

In some embodiments, at least one of or each of the stackable layers (e.g., substrates 904a-c) of a display (e.g., display 901 or any suitable display described throughout the present disclosure) may comprise optical components (e.g., LED chips 906a-c, and mirrors) reconstituted in a substrate 904a-c. For example, the mirrors may be formed and included in each substrate 904a-c.

The top-most LEDs 906c is embedded in or disposed in a respective dielectric layer 908c of the top substrate 904c. In some embodiments, the dielectric layer 908c may comprise any suitable dielectric material, such as those mentioned in the present disclosure. In some embodiments, the dielectric layer 908c may comprise an optically tuned dielectric that reduces the absorption of the light transmitted by the LEDs 906a-c. The LEDs 906c may emit light 930 to directly exit a display surface of the display 901. For example, there may be no intermediary component changing the direction of light emitted from the LED 906c.

The intermediate LEDs 906b is embedded in or disposed in a respective dielectric layer 908b of the intermediate substrate 904b. In some embodiments, the dielectric layer 908c may comprise any suitable dielectric material, such as those mentioned in the present disclosure. In some embodiments, the dielectric layer 908c may comprise an optically tuned dielectric that reduces the absorption of the light transmitted by the LEDs 906a. The intermediate LEDs 906b may emit light 932 that is guided by mirrors 912 to exit a display surface of the display 901. For example, there may be an intermediary component (e.g., mirrors 912) changing the direction of light 932 emitted from LEDs 906b.

The bottom LEDs 906a is embedded in or disposed in a respective dielectric layer 908a of the intermediate substrate 904a. In some embodiments, the dielectric layer 908c may comprise any suitable dielectric material, such as those mentioned in the present disclosure. The bottom LEDs 906a may emit light 931 that is guided by mirrors 918 to exit a display surface of the display 901. For example, there may be an intermediary component (e.g., mirrors 918) changing the direction of light 931 emitted from LEDs 906a.

The first layer 910 is disposed between the intermediate substrate 904b and the top substrate 904c. The first layer 910 comprises first mirrors 912 to direct light from respective LEDs 906b of the intermediate substrate 904b towards a display side of the display 901. In some embodiments, the first mirrors 912 comprise a dichroic film which allows the transmission of wavelengths emitted from the singulated LEDs 906a of the bottom substrate 904a while concurrently reflecting wavelengths emitted from the singulated LEDs 906b of the intermediate substrate 904b.

The second layer 916 is disposed between the bottom substrate 904a and the intermediate substrate 904b. The second layer 916 comprises second mirrors 918 to direct light from respective LEDs 906a of the bottom substrate 904a towards the display side of the display 901. The second mirrors 918 may not comprise a dichroic film. The second mirrors 918 may comprise a broad band reflecting material (e.g., Al, Ag, Distributed Bragg Reflector (DBR) coatings, etc.,). For example, the second mirrors 918 may not be dichroic mirrors. The second mirrors 918 may be a fully reflective mirror.

FIG. 9C schematically illustrates a display 911 (e.g., display device, LED display or display device, micro-LED display or display device), according to some embodiments. FIG. 9C shows a cross section view of a single pixel for display device. The display device may have similar features to the display device described above, and therefore the description of similar features is omitted for brevity. In some embodiments, the display device 911 is the same as display device 901 of FIGS. 9A-9B except a third layer 920 is disposed on the top substrate 904c. The third layer 920 comprises third mirrors 922 that direct light 930 from LEDs 906c of the top substrate 904c towards the display side of the display device. It is understood that substrates 904a, 904b, and 904c as well as layers 910 and 916 can have through substrates vias for electrical connectivity from top to bottom.

In some embodiments, light emitted from a single pixel by LEDs 906a-c travel along a same or similar indirect path (e.g., portion of display where light 931, 932, and 930 are reflected by corresponding mirrors 918, 912, and 922 towards a display surface to exit a display). In some embodiments each the stackable layers 908a-c of the display device comprises of optical components (e.g., LED chips 906a-c, and mirrors) reconstituted in a substrate 904a-c.

FIG. 9D schematically illustrates a display 921 (e.g., display device, LED display or display device, micro-LED display or display device), according to some embodiments. FIG. 9C shows a cross-sectional view of a single pixel of display device. The LED 906a of the bottom substrate 904a is offset with respect to LEDs 906b and 906c in the intermediate substrate 904b and top 904c substrate. This offset enables light 931 emitted from the LED 906a to be transmitted directly towards the display side without having a dedicated reflector layer (e.g. layer 916 and mirrors 918). The light 931 emitted from LED 906a passes through the first mirrors 912 (e.g., at least one of a pair of first mirrors 912). The first mirrors 912 (e.g., at least one of a pair of first mirrors 912) may comprise a dichroic film to allow the transmission of wavelengths or light 931 emitted from the singulated LEDs 906a of the bottom substrate 904a while concurrently reflecting wavelengths or light 932 emitted from the singulated LEDs 906b of the intermediate substrate 904b. This offset allows for the removal of the second layer 916 comprising the second mirrors 918 from the display 901 of FIG. 9B to form the display of FIG. 9C. In some embodiments, one of a pair of first mirrors 912 may comprise a mirror (e.g., receiving light from LED 906b) and one of a pair of first mirrors 912 may comprise a dichroic film (e.g., receiving light 932 from the other one of the pair of mirrors to reflect towards a surface of a display). In some embodiments, both of a pair of first mirrors may comprise a dichroic film.

FIG. 10 shows a schematic of an example method for forming a layer of a display device. In some embodiments, singulated LED 1006 from RGB wafers can be integrated to form a composite RGB pixel. In some embodiments, the example method shows forming a substrate. In some embodiments, singulated LED 1006 may correspond to (e.g., be similar to or same as) any suitable LED described in the present disclosure.

At block 10, the method includes singulating a wafer to form pixel-size chips or chiplets. For example, a wafer of singulated LEDs 1006 may be placed on a tape frame or temporary carrier 1016 and singulated to form LED chips or chiplets. The singulated LED chips or chiplets may be about 1×1 micron², about 5×5 micron², about 10×10 micron², to about 40×40 micron² or any suitable LED size for a pixel. In some embodiments, any suitable wafer (e.g., wafer of blue LEDs, wafer of green LEDs, wafer of any suitable color, etc.) may be placed on a tape frame and singulated. The method may further include stretching the temporary carrier 1016 to space apart neighboring chips or LEDs (e.g., singulated LEDs 1006).

At block 11, the method includes spacing apart singulated chips or chiplets. In some embodiments, the method of spacing singulated LED chips (e.g., singulated LEDs 1006) from diced wafers may include separation via dicing tape expansion (e.g., stretching temporary carrier 1016). For example, the temporary carrier 1016 may be stretched to create uniform spacing between neighboring singulated LEDs (e.g., singulated LEDs 1006). A spacing of about 1 to 40 microns between neighboring singulated LEDs (e.g., singulated LEDs 1006) may be formed as based on a desired pixel size. In some embodiments, after stretching the chiplets on a first tape, the spaced-apart chiplets may be transferred to a second tape for a second stretching operation. Multiple stretching operations may be performed to obtain the desired lateral spacing between the chiplets before subsequent operations. One of the subsequent operations may comprise transferring the chiplets to a carrier.

At block 12, the method includes transferring the singulated chips or chiplets to a carrier substrate. For example, singulated LEDs 1006 are transferred to a carrier substrate 1020 via bonding or adhesive. Before or after transferring, diffusion regions may be removed from the LEDs and first electrodes 1023 may be formed. In some embodiments, both electrodes (e.g., first and second electrodes) may be formed to the LEDs based on the design. The method may include forming a reflective layer 1026 over the plurality of singulated LED (e.g., singulated LEDs 1006). The reflective layer 1026 may comprise a reflective metal (e.g., Ag, Au, or Al, etc.) or DBR coatings. One or more dielectric layers (e.g., adhesion, isolation, passivation, barrier, etc.) may be deposited before and/or after the reflective layer 1026 is formed. In some embodiments, the reflective layer may comprise of a distributed Bragg reflector. In some embodiments, a reflective material (e.g., reflective layer 1026) may be coated on non-light-emitting sides of each LED 1006. In some embodiments, a light-absorbing layer may be disposed or positioned between adjacent LEDs 1006. The light-absorbing layer comprising a light-absorbing material may be disposed between the reflective layer 1026 and a dielectric layer 1008. The light-absorbing material may significantly reduce optical crosstalk between neighboring LEDs 1006. In some embodiments, the light-absorbing material comprises a metallic, resin, or polymer material.

At block 13, the method includes forming a reconstitution dielectric over the singulated chips or chiplets. For example, the dielectric layer 1008 is formed over the reflective layer 1026. The dielectric layer 1008 may comprise silicon oxide or a suitable dielectric material tuned to transmit a specific wavelength range (e.g., corresponding to a color of light emitted from an LED of bonded adjacent substrate behind/below dielectric layer 1008).

At block 14, the method includes forming electrical connectors to the chip or chiplets. For example, electrical connectors 1024 are formed to contact the electrodes 1023 of singulated LEDs 1006. The method may include forming vias 1028a and 1028b through the dielectric layer 1008. The vias 1028a-b may enable electrical connections through the dielectric layer 1008 to neighboring substrates via hybrid bonding. The electrical connectors 1024 and vias 1028a-b may comprise a same or different material and may be any suitable conductive material such as those described in the present disclosure. In some embodiments, the method of forming the electrical connectors 1024 and vias 1028a-b may comprise depositing or coating a suitable adhesion layer over a patterned cavity corresponding to the electrical connector 1024 and/or vias 1028a-b, over filling the patterned cavity with a suitable conductive layer, and planarizing the conductive layer to remove unwanted materials (e.g., overburden of material, excess material, a portion of material to help planarize a surface). The unwanted materials may comprise portions of the conductive layer, the adhesion layer, and the dielectric layer 1008. In some embodiments, the connectors 1024 and vias 1028a-b may comprise wirebonds, formed by wirebonding operations. In other embodiments, the connectors 1024 and vias 1028a-b may be formed by 3D printing methods or screen printing methods.

At block 15, the method includes forming a direct bonding interface (DBI) layer (e.g., bottom DBI layer). For example, the method comprises forming a redistribution layer 1040 comprising conductive features or bond pads 1034 and interconnects 1038 in a dielectric layer.

At block 16, the method includes transferring the reconstituted wafer to another substrate. For example, the method includes transferring the reconstituted singulated singulated LEDs 1006 and redistribution layer 1040 to substrate 1022 (e.g., another carrier or a target wafer) and removing the first carrier 1020. In some embodiments, the reconstituted wafer comprising singulated LEDs 1006 can be transferred to or hybrid bonded to another reconstituted wafer (comprising LEDs and/or control device) or another wafer comprising control devices (e.g., control or controller device wafer, device wafer, ROIC wafer, full wafer, etc.). The method may include forming second electrodes 1032 of the LEDs 1006. The method may include forming another DBI layer (e.g., top DBI layer). For example, the method includes forming a redistribution layer 1040 comprising interconnects 1038 and bond pads 1034 in a dielectric layer.

In some embodiments, the method shown in FIG. 10 can be modified to form any suitable substrates such as those mentioned in the present disclosure. For example, at block 16, method may include multiple transfer steps, where different types of LEDs (e.g., singulated wafer of red LEDs, singulated wafer of green LEDs, singulated wafer of blue LEDs, etc.) and/or singulated control devices may be transferred.

In some embodiments, the method includes hybrid bonding to electrically connect each control device to one or more of the LEDs to form a pixel. For example, at block 14 the substrate 1022 may be a target substrate and the reconstituted wafer may be a substrate. For example, the substrate may be hybrid bonded to additional substrates (e.g., via redistribution layer 1040) and the substrate may be hybrid bonded to a processor substrate, reconstituted substrate or wafer, etc. (e.g., via redistribution layer 1040). Hybrid bonding the substrate to a processor substrate may electrically connect a control device to one or more LEDs of the second substrates. Each control device and the one or more LEDs electrically connected thereto may form a pixel.

In some embodiments, where there are more than one stacked layer, the display may further comprise light guides. For example, the method may include forming deep-trench isolation with metal fill that guides light emitted from the LEDs of at least of the first substrates or the second substrate to a surface of the display. For example, the method may include forming channels with metal coatings to form light guides. In some embodiments, the method may include forming a dielectric fill on the metal coatings in the channels.

The embodiments discussed above are intended to be illustrative and not limiting. One skilled in the art would appreciate that individual aspects of the display and display device, and methods discussed herein may be omitted, modified, combined, and/or rearranged without departing from the scope of the disclosed subject matter.

It is contemplated that any combination of the methods described above may be used to form a display whether or not expressly recited herein.

The embodiments discussed above are intended to be illustrative and not limiting. One skilled in the art would appreciate that individual aspects of the display and display device, and methods discussed herein may be omitted, modified, combined, and/or rearranged without departing from the scope of the disclosure.

1. A display device comprising:
a plurality of singulated dies attached to a backplane, wherein each singulated die comprises a plurality of LEDs.

2. The display device of claim 1, wherein:
the singulated dies are singulated first dies;
the LEDs are first LEDs; and
the display device further comprises a plurality of singulated second dies overlaying the plurality of singulated first dies, each singulated second die comprising a plurality of second LEDs.

3. The display device of claim 1, wherein each die has an LED driver.

4. The display device of claim 1, wherein each die has a sensor.

5. The display device of claim 1, wherein at least one replacement die is disposed to overlap at least one die.

6. The display device of claim 2, wherein at least one replacement first die and at least one replacement second die is disposed to overlap at least one singulated first die and at least one singulated second die.

7. The display device of claim 2, wherein:
the first LEDs and second LEDs are edge emitting LEDs;
each singulated first die further comprises a plurality of first waveguides;
each singulated second die further comprises a plurality of second waveguides;
light emitted from the first LEDs is guided by the first waveguides through the second waveguides towards a viewing surface of the display device; and
light emitted by the plurality of second LEDs is guided by the second waveguides towards the viewing surface of the display device.

8. The display device of claim 2, wherein the plurality of second LEDs are surface emitting LEDs.

9. The display device of claim 2, further comprising a plurality of singulated third dies disposed between the plurality of singulated first dies and the plurality of singulated second dies, each singulated third die comprising a plurality of third LEDs.

10. The display device of claim 9, wherein:
the plurality of third LEDs are edge-emitting LEDs; and
each singulated third die may further comprise a plurality of third waveguides.

11. The display device of claim 9, wherein at least one replacement third die is disposed to overlap at least one singulated third die.

12. The display device of claim 2, wherein each die is directly hybrid bonded to a vertically adjacent die without use of an intervening adhesive.

13. A method of forming a display device comprising:
providing a plurality of singulated dies, each singulated die comprising a plurality of LEDs; and
attaching the plurality of singulated dies to a backplane.

14. The method of claim 13, wherein:
the singulated dies are singulated first dies;
the LEDs are first LEDs; and
the method further comprises:
providing a plurality of singulated second dies, each singulated second die comprising a plurality of second LEDs; and
attaching the singulated second dies to overlay the singulated first dies.

15. The method of claim 13, further comprising attaching at least one replacement die to overlap at least one singulated die.

16. The method of claim 14, further comprising attaching at least one replacement first die and at least one replacement second die to overlap at least one singulated first die and at least one singulated second die.

17. The method of claim 13, wherein:
the singulated dies are singulated first dies;
the LEDs are first LEDs; and
the method further comprises:
providing a plurality of singulated second dies, each singulated second die comprising a plurality of second LEDs;
providing a plurality of singulated third dies, each singulated third die comprising a plurality of third LEDs;
attaching the singulated third dies to overlay the singulated first dies; and
attaching the singulated second dies to overlay the singulated third dies.

18. The method of claim 14, wherein each die is directly hybrid bonded to a vertically adjacent die without use of an intervening adhesive.

19. The method of claim 13, wherein:
the plurality of singulated dies comprises a plurality of first singulated dies and second singulated dies;
each first singulated die comprises a plurality of first LEDs and first waveguides;
each second singulated die comprises a plurality of second LEDs and second waveguides; and
attaching the plurality of singulated dies to the backplane comprises:
directly hybrid bonding first singulated dies to second singulated dies to form stacked dies; and
directly hybrid bonding the stacked dies to the backplane, wherein light emitted from the first LEDs is guided by the first waveguides through the second waveguides towards a viewing surface of the display device.

20. The method of claim 13, wherein:
the singulated dies are singulated stacked dies, each singulated stacked die comprising a singulated first die and a singulated second die, the singulated first die comprising a plurality of first LEDs and first waveguides and the singulated second die comprising a plurality of second LEDs and second waveguides;
providing the plurality of singulated dies comprises hybrid bonding a first wafer and a second wafer to form stacked wafers and dicing the stacked wafers to form stacked dies; and
attaching the plurality of singulated dies to the backplane comprises directly hybrid bonding the plurality of singulated stacked dies to the backplane; and
light emitted from the first LEDs is guided by the first waveguides through the second waveguides towards a viewing surface of the display device.
